(19) United States
(12) Patent Application Publication
(10) Pub. No.: US 2026/0182149 A1
(43) Pub. Date: Jun. 25, 2026

(54) DISPLAY DEVICE

(71) Applicant: LG Display Co., Ltd., Seoul (KR)

(72) Inventor: Jong Ho KIM, Paju-si (KR)

(73) Assignee: LG Display Co., Ltd., Seoul (KR)

(21) Appl. No.: 19/427,679

(22) Filed: Dec. 19, 2025

(30) Foreign Application Priority Data
Dec. 24, 2024 (KR) 10-2024-0195707

(51) Int. Cl. H10K 59/121; H10D 86/40; H10D 86/60; H10K 59/35

(52) U.S. Cl. CPC H10K 59/1213; H10D 86/423; H10D 86/60; H10K 59/353

(57) ABSTRACT

Discussed is a display device including a substrate; a first subpixel, a second subpixel, and a third subpixel disposed on the substrate, the first subpixel emitting light of a first wavelength, the second subpixel emitting light of a second wavelength shorter than the light of the first wavelength, and the third subpixel emitting light of a third wavelength shorter than the light of the second wavelength; a first driving transistor at the first subpixel, a second driving transistor at the second subpixel, and a third driving transistor at the third subpixel, and the first, second and third transistors being on the substrate; and a plurality of switching transistors at the first, second and third subpixels, respectively, wherein a first active layer of the first driving transistor and a third active layer of the third driving transistor have active spacers.

### CROSS-REFERENCE TO RELATED APPLICATIONS

This application claims priority to Korean Patent Application No. 10-2024-0195707, filed in the Republic of Korea on December 24, 2024, the entire contents of which is hereby expressly incorporated by reference into the present application.

### BACKGROUND OF THE DISCLOSURE

### Field of the Disclosure

The present disclosure relates to a display device, and more specifically, to a display device capable of improving reliability and reducing power consumption.

### Discussion of the Related Art

Display devices are used in various manners and forms to display images, and examples of such display devices include TVs, monitors, smartphones, tablets, and laptops.

Display devices further include a display panel having a plurality of light-emitting elements or liquid crystal for displaying images, and transistors are used for controlling the operations of light-emitting elements or liquid crystal to display an image as desired through the plurality of light-emitting elements or liquid crystal.

A display device specifically use a plurality of pixels, and a plurality of driving and switching elements for driving and controlling each pixel. The driving and switching elements can be configured as the transistors, and transistors are widely applied not only to pixels in an active area but also to integrated circuits in a non-active area.

Recently, various research and development has been conducted to improve the performance and reliability of transistors in order to improve the reliability and reduce power consumption of display devices.

### SUMMARY OF THE DISCLOSURE

Accordingly, the present disclosure is directed to a display device that substantially obviates one or more problems due to limitations and disadvantages of the related art.

An aspect of embodiments of the present disclosure is to provide a display device in which positive bias temperature stress (PBTS) characteristics of a driving transistor of each subpixel are stabilized.

An aspect of the embodiments of the present disclosure is to provide a display device for reducing stress of driving transistors of subpixels, preventing deterioration of the driving transistors, and reducing power consumption by reducing the threshold voltage of the driving transistors.

An aspect of the embodiments of the present disclosure is to provide a display device capable of matching the current characteristics and set values required for subpixels that display different colors.

An aspect of the embodiments of the present disclosure is to provide a display device having transistors including an oxide semiconductor layer and having improved reliability.

An aspect of the embodiments of the present disclosure is to achieve ESG (Environmental/Social/Governance) by improving the reliability of a display device and reducing power consumption.

The aspects of the embodiments of the present disclosure are not limited to the aspects mentioned above, and other aspects not mentioned can be clearly understood by those skilled in the art from the description below.

Additional advantages, aspects, and features of the present disclosure will be set forth in part in the description which follows and in part will become apparent to those having ordinary skill in the art upon examination of the following or can be learned from practice of the present disclosure. The aspects and other advantages of the present disclosure can be realized and attained by the structure particularly pointed out in the written description and claims hereof as well as the appended drawings.

To achieve these objects and other advantages and in accordance with the purpose of the present disclosure, as embodied and broadly described herein, a display device includes a substrate on which a first subpixel emitting light of a first wavelength, a second subpixel emitting light of a second wavelength shorter than the first wavelength, and a third subpixel emitting light of a third wavelength shorter than the second wavelength are disposed, a first driving transistor of the first subpixel, a second driving transistor of the second subpixel, and a third driving transistor of the third subpixel, disposed on the substrate, and a plurality of switching transistors disposed in the first to third subpixels, wherein a first active layer of the first driving transistor and a third active layer of the third driving transistor have active spacers in regions where the first active layer and the third active layer overlap gate electrodes of the first driving transistor and the third driving transistor, the active spacers being spaces in which the active layers are separated.

The active spacers may not overlap a first source-drain electrode and a second source-drain electrode of each of the first driving transistor and the third driving transistor, and can be disposed parallel to a direction of channel lengths of the first active layer and the third active layer.

The display device can further include a gate insulating layer disposed between gate electrodes of the first driving transistor, the second driving transistor, and the third driving transistor, and the first active layer and the third active layer on the substrate, and an insulating layer disposed between the first active layer and the third active layer and the substrate, wherein the gate insulating layer is disposed in the active spacers, and the gate insulating layer is in contact with the insulating layer disposed under the active layers in the active spacers.

The active spacers can extend in both directions from regions overlapping the gate electrodes of the first driving transistor and the third driving transistor toward the first source-drain electrode and the second source-drain electrode and protrude from edges of the gate electrodes to have regions not overlapping the gate electrodes, and the active spacers are disposed to extend parallel to the channel length of the active layers.

The regions of the active spacers overlapping the gate electrodes of the first and third driving transistors and the regions of the active spacers extending in both directions toward the first source-drain electrode and the second source-drain electrode of the first and third driving transistors and not overlapping the gate electrodes are one body.

The size of the region of the active spacer overlapping the gate electrode of each of the first and third driving transistors can be greater than the size of the region of the active spacer not overlapping the gate electrode of each of the first and third driving transistors.

Based on a direction parallel to an imaginary line crossing the first source-drain electrode and the second source-drain electrode of each of the first and third driving transistors being defined as a first direction, and a direction perpendicular to the first direction being defined as a second direction, the length of the active spacer in the first direction can be greater than the length of the active spacer in the second direction.

Based on a direction parallel to an imaginary line crossing the first source-drain electrode and the second source-drain electrode of each of the first driving transistors being defined a first direction, and a direction perpendicular to the first direction being defined as a second direction, the first active layer can include a first region and a second region spaced apart in the second direction with the active spacer interposed between the first region and the second region, and an active connection portion connecting the first region and the second region in the first direction and not overlapping the gate electrode of the first driving transistor, and mobility of the active connection portion can be greater than mobility of the first region and the second region.

Mobility of an edge of the first region in the region overlapping the gate electrode of the first driving transistor can be greater than mobility of a center of the first region, and mobility of an edge of the second region in the region overlapping the gate electrode of the first driving transistor can be greater than mobility of a center of the second region.

Mobility of the first region in contact with the edge of the active spacer can be greater than mobility of the first region away from the edge of the active spacer, and mobility of the second region in contact with the edge of the active spacer can be greater than mobility of the second region away from the edge of the active spacer.

The first subpixel can display red, the second subpixel can display green, and the third subpixel can display blue.

It is to be understood that both the foregoing general description and the following detailed description of the present disclosure are example and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a schematic plan view of a display device according to an embodiment of the present disclosure;

FIG. 2 is a plan view of area A of FIG. 1;

FIG. 3 is a circuit diagram of a subpixel of a display device according to an embodiment of the present disclosure;

FIG. 4 is a circuit diagram of a subpixel of a display device according to another embodiment of the present disclosure;

FIG. 5 is a cross-sectional view illustrating a display device according to an embodiment of the present disclosure;

FIG. 6 is a plan view illustrating a switching transistor and a driving transistor of a first subpixel of FIG. 5;

FIG. 7 is a cross-sectional view taken along line I-I’ in FIG. 6 according to an embodiment of the present disclosure;

FIG. 8 is a cross-sectional view taken along line I-I’ in FIG. 6 according to another embodiment of the present disclosure;

FIG. 9 is a plan view illustrating a switching transistor and a driving transistor of a second subpixel of FIG. 5;

FIG. 10 is a cross-sectional view taken along line II-II’ in FIG. 9;

FIG. 11 is a plan view illustrating a switching transistor and a driving transistor of a third subpixel of FIG. 5;

FIG. 12 is a cross-sectional view taken along line III-III’ in FIG. 11; and

FIG. 13 is a graph showing effects according to an embodiment of the present disclosure through threshold voltage data of driving transistors of subpixels.

### DETAILED DESCRIPTION OF THE EMBODIMENTS

Hereinafter, embodiments will be described with reference to the drawings.

The same or extremely similar elements are designated by the same reference numerals throughout the specification, and in the drawings, the lengths and thickness of layers and regions can be exaggerated for convenience. The scale of the components shown in the drawings is different from the actual scale, and is not limited to the scale shown in the drawings.

It will be understood that, when a certain element (or a region, a layer, or a portion) is referred to as being “on”, “connected to” or “combined with” another element, the element can be directly connected/combined to/with the other element, or a third element can be interposed therebetween.

“And/or” includes any combination of one or more of the associated components.

While terms, such as “first”, “second”, etc., can be used to describe various components, such components must not be limited by the above terms. The above terms are used only to distinguish one component from another. In addition, terms particularly defined in consideration of construction and operation of the embodiments are used only to describe the embodiments and do not define the scope of the embodiments.

In the description of the embodiments, it will be understood that, when an element is referred to as being formed “on” or “under” another element, it can be directly “on” or “under” the other element or be indirectly formed with intervening elements therebetween. It will also be understood that, when an element is referred to as being “on” or “under”, “under the element” as well as “on the element” can be included based on the element.

It will be further understood that the terms “comprise” and “include” specify the presence of stated features, integers, steps, operations, elements, components, and/or combinations thereof, but do not preclude the presence or addition of one or more other features, integers, steps, operations, elements, components, and/or combinations.

The respective features of the various embodiments of the present disclosure can be partially or wholly coupled to and combined with each other, and various technical linkage and driving thereof are possible. These various embodiments can be performed independently of each other, or can be performed in association with each other.

The term “made of” for an element can fully encompass the meaning of being completely formed of the element, or simply including the element, and the term "can" fully encompasses all the meanings and coverages of the term "may."

Hereinafter, a display device of the present disclosure will be described with reference to the attached drawings and embodiments.

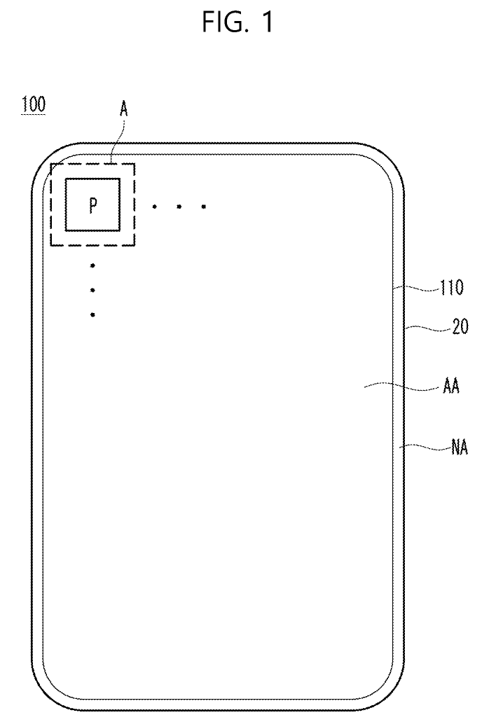

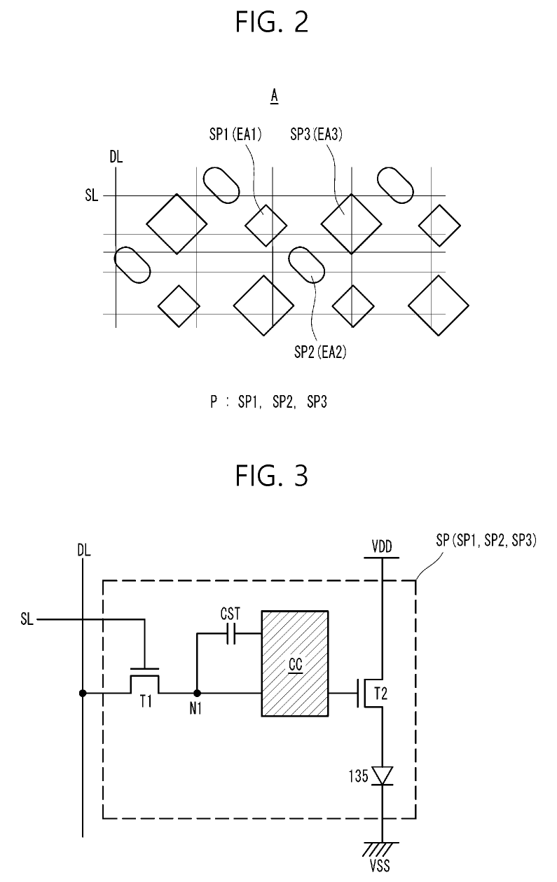

FIG. 1 is a schematic plan view of a display device according to embodiments of the present disclosure, and FIG. 2 is a plan view of area A of FIG. 1. All components of each display device according to all embodiments of the present disclosure are operatively coupled and configured.

Referring to FIG. 1 and FIG. 2, a display device 100 according to an embodiment of the present disclosure includes a display panel 110 including an active area AA and a non-active area NA, and a cover member 20 disposed on the display panel 110.

The cover member 20 is disposed on the display panel 110 to cover the front of the display panel 110 and protect the display panel 110 from external impact. The edge of the cover member 20 can have a curved portion or a curved surface portion that is bent in the direction (-Z-axis direction) of the back surface of the display device 100. Accordingly, the cover member 20 can cover the side area of the display panel 110, and thus the display panel 110 can be protected from external impact not only on the front but also on the side of the display device 100.

The active area AA of the display device 100 is an area for displaying an image, and an area other than the active area AA is a non-active area NA. The active area AA and the non-active area NA of the display device 100 are applied equally to the display panel 110.

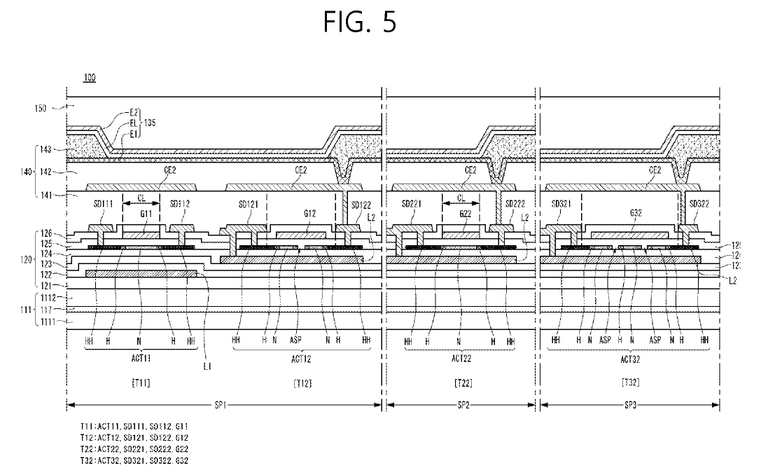

The display device 100 includes a substrate (111 in FIG. 5) having both the active area AA and the non-active area NA. The definition of the active area AA can be applied equally to the substrate.

As illustrated in FIG. 2, a plurality of data lines DL extending in a first direction and a plurality of scan lines SL extending in a second direction intersecting the first direction can be disposed in the active area AA on the substrate.

Subpixels (for example, SP1, SP2, and SP3) can be disposed at intersections of the data lines DL and the scan lines SL. One subpixel SP1, SP2, or SP3 can be defined as an emission area. One subpixel SP1, SP2, or SP3 is not limited to the region defined by intersection of a data line DL and a scan line SL.

The first subpixel SP1, the second subpixel SP2, and the third subpixel SP3 can emit different colors. The first subpixel SP1 can emit light of a first wavelength, the second subpixel SP2 can emit light of a second wavelength, and the third subpixel SP3 can emit light of a third wavelength. The second wavelength can be shorter than the first wavelength, and the third wavelength can be shorter than the second wavelength.

For example, the first wavelength can be in a red wavelength range, the second wavelength can be in a green wavelength range, and the third wavelength can be in a blue wavelength range. The first subpixel SP1 can display red R, the second subpixel SP2 can display green G, and the third subpixel SP3 can display blue B.

The first subpixel SP1 can have a first emission area EA1, the second subpixel SP2 can have a second emission area EA2, and the third subpixel SP3 can have a third emission area EA3. The first emission area EA1 can emit red R, the second emission area EA2 can emit green G, and the third emission area EA3 can emit blue B.

The first subpixel SP1, the second subpixel SP2, and the third subpixel SP3 can constitute one pixel P. The active area AA can include an area where a camera or a sensor is located.

The first subpixel SP1, the second subpixel SP2, and the third subpixel SP3 can have the same circuit configuration.

FIG. 3 is a circuit diagram of a subpixel SP of the display device according to an embodiment of the present disclosure. Referring to FIG. 3, one subpixel SP can include a switching transistor T1, a driving transistor T2, a capacitor Cst, a compensation circuit CC, and a light-emitting element 135.

The switching transistor T1 is electrically connected to a data line DL and electrically connected to a first node N1. The gate electrode of the switching transistor T1 is electrically connected to a scan line SL. The switching transistor T1 transmits a data signal supplied through the data line DL to the first node N1 in response to a scan signal supplied through the scan line SL.

The capacitor Cst is electrically connected to the first node N1 and is charged with a voltage applied to the first node N1.

The driving transistor T2 receives a high-level driving voltage VDD and is electrically connected to the first electrode (e.g., anode) of the light-emitting element 135. The driving transistor T2 can control the amount of driving current flowing through the light-emitting element 135 in response to a voltage applied to the gate electrode.

Semiconductor layers of the switching transistor T1 and the driving transistor T2 can include an oxide semiconductor material such as Indium-Gallium-Zinc-Oxide (IGZO).

The light-emitting element 135 emits light corresponding to the driving current. The light-emitting element 135 can emit light of one of red, green, blue, and white.

The light-emitting element 135 can include a first electrode, an emission layer disposed on the first electrode, and a second electrode supplying a common voltage. The emission layer can emit light of the same color for each subpixel, such as white light, or can emit light of different colors for each subpixel SP, such as red, green, or blue light.

The first electrode serves as an anode, and the second electrode serves as a cathode. The light-emitting element 135 can be a front emission diode or a back emission diode. The light-emitting element 135 is substantially the same as a light-emitting element (135 in FIG. 5) which will be described below.

The compensation circuit CC can be provided in the first subpixel SP1 to compensate for the threshold voltage of the driving transistor T2. The compensation circuit CC can be composed of one or more transistors. The compensation circuit CC can include one or more transistors and a capacitor, and can be configured in various manners depending on the compensation method. A subpixel including the compensation circuit CC can have various structures such as 3T1C, 4T2C, 5T2C, 6T1C, 6T2C, 7T1C, and 7T2C, but the embodiments of the present disclosure are not limited thereto, and other arrangements can be used. For example, a plurality of transistors can be electrically connected between the driving transistor T2 and the light-emitting element 135.

In the embodiment of FIG. 3, the light-emitting element 135 can be an organic light-emitting diode, but the present disclosure is not limited thereto, and various types of light-emitting elements can be employed. The transistors including the switching transistor T1 and the driving transistor T2 of the present disclosure can have a double gate structure in which gate electrodes are positioned on and under an active layer.

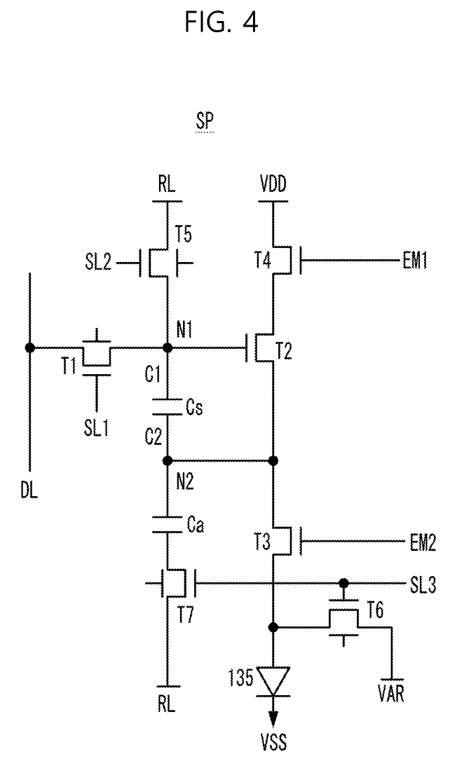

FIG. 4 is a circuit diagram of a subpixel SP of a display device according to another embodiment of the present disclosure. Referring to FIG. 4, the subpixel SP includes a switching transistor T1, a driving transistor T2, a third transistor T3, and a light-emitting element 135 electrically connected to the third transistor T3. The subpixel SP further includes a first capacitor Cs electrically connected to the driving transistor T2 and the third transistor T3. The subpixel SP can further include fourth to seventh transistors T4, T5, T6, and T7 and a second capacitor Ca.

Each of the first to seventh transistors T1, T2, T3, T4, T5, T6, and T7 can be a p-type transistor or an n-type transistor. Each of the first to seventh transistors T1, T2, T3, T4, T5, T6, and T7 is turned on when a high voltage is applied to the gate electrode thereof.

The switching transistor T1 is connected to a data line DL to supply data.

The gate electrode of the switching transistor T1 is connected to a first scan line SL1, the first source-drain electrode of the switching transistor T1 is connected to the data line DL, and the second source-drain electrode of the switching transistor T1 is connected to a first capacitor electrode C1 of the first capacitor Cs at a first node N1 and a gate electrode of the driving transistor T2.

The driving transistor T2 is connected to the switching transistor T1.

An upper gate electrode of the driving transistor T2 is connected to the second source-drain electrode of the switching transistor T1 at the first node N1, and the driving transistor T2 can be disposed between the third transistor T3 and the fourth transistor T4.

A first source-drain electrode of the driving transistor T2 is connected to the fourth transistor T4 to which a high-level driving voltage VDD is supplied, and a second source-drain electrode of the driving transistor T2 is connected to a first source-drain electrode of the third transistor T3 at a second node N2.

The driving transistor T2 supplies a driving current flowing between the third and fourth transistors T3 and T4 to the first electrode of the light-emitting element 135 through the second node N2 according to signals applied to first and second emission lines EM1 and EM2.

The driving transistor T2 can further include a lower gate electrode.

The first source-drain electrode of the third transistor T3 can be connected to the second source-drain electrode of the driving transistor T2 at the second node N2, and the second source-drain electrode thereof can be connected to the first electrode of the light-emitting element 135.

The third transistor T3 transmits a signal proportional to the high-level driving voltage or a signal proportional to an initialization voltage Vini to the light-emitting element 135 according to the signal supplied to the second emission line EM2.

The gate electrodes of the fourth transistor T4 and the third transistor T3 are connected to the first and second emission lines EM1 and EM2. The fourth transistor T4 and the third transistor T3 can adjust supply of the driving current to the light-emitting element 135.

The first source-drain electrode of the fourth transistor T4 is connected to a first power voltage line through which the high-level driving voltage VDD is supplied, and the second source-drain electrode of the fourth transistor T4 is connected to the first source-drain electrode of the driving transistor T2.

The fourth transistor T4 can supply a voltage proportional to the high-level driving voltage to the first source-drain electrode of the driving transistor T2 according to the signal supplied through the first emission line EM1.

The fifth transistor T5 is connected to a reference voltage line RL to supply a reference voltage to the first capacitor electrode C1 of the first capacitor Cs.

The gate electrode of the fifth transistor T5 is connected to the second scan line SL2, the first source-drain electrode of the fifth transistor T5 is connected to the reference voltage line RL, and the second source-drain electrode of the fifth transistor T5 is connected to the first electrode C1 of the first capacitor Cs and the gate electrode of the driving transistor T2 at the first node N1. Here, the first source-drain electrode of the fifth transistor T5 can be electrically connected to the lower gate electrode of the driving transistor T2.

When a gate signal is applied to the gate electrode of the fifth transistor T5 through the second scan line SL2, the reference voltage through the fifth transistor T5 is applied to the first capacitor electrode C1 of the first capacitor Cs through the first node N1.

The sixth transistor T6 transmits a reset voltage to the light-emitting element 135. The sixth transistor T6 can serve as an initialization transistor.

The gate electrode of the sixth transistor T6 is connected to a third scan line SL3, the first source-drain electrode of the sixth transistor T6 is connected to a reset line VAR through which the reset voltage is supplied, and the second source-drain electrode thereof is connected to the second source-drain electrode of the third transistor T3.

When a signal through the third scan line SL3 is applied to the gate electrode of the sixth transistor T6, the sixth transistor T6 transmits the reset voltage to the first electrode of the light-emitting element 135.

The second capacitor Ca is connected between the second node N2 and the reference voltage line RL. The second capacitor Ca is an auxiliary capacitor and is connected to the reference voltage line RL through which the reference voltage is applied to maintain the voltage of the second node N2 at the reference voltage or higher.

When a signal is supplied to the gate electrode of the seventh transistor T7 through the third scan line SL3, a voltage proportional to the reference voltage transmitted to the reference voltage line RL can be transmitted to one electrode of the second capacitor Ca.

The light-emitting element 135 includes a first electrode, an emission layer, and a second electrode. The first electrode of the light-emitting element 135 is connected to the second source-drain electrode of the third transistor T3, a voltage proportional to the high-level driving voltage is supplied through the first power voltage line VDD, the second electrode of the light-emitting element 135 is connected to a second power voltage line VSS, and a low-level driving voltage is supplied through the second power voltage line VSS.

The light-emitting element 135 can emit light of any one of white, red, green, and blue.

In the display device according to an embodiment of the present disclosure, the first and third to seventh transistors T1, T3, T4, T5, T6, and T7 can have lower gate electrodes, and can have a configuration in which the threshold voltages thereof are controlled in a different manner from controlling the threshold voltage of the driving transistor T2 that supplies the driving current.

Referring to FIG. 5, in the display device 100 to which the subpixel shown in FIG. 3 or FIG. 4 is applied, a first subpixel SP1 emitting light of a first wavelength, a second subpixel SP2 emitting light of a second wavelength, and a third subpixel SP3 emitting light of a third wavelength are disposed on a substrate 111.

As described above, the second wavelength can be shorter than the first wavelength, and the third wavelength can be shorter than the second wavelength.

For example, the first wavelength can be in a red wavelength range, the second wavelength can be in a green wavelength range, and the third wavelength can be in a blue wavelength range. Further, the first wavelength can be in a range of 590 nm to 700 nm, the second wavelength can be in a range of 495 nm to 570 nm, and the third wavelength can be in a range of 430 nm to 495 nm, but the embodiments of the present disclosure are not limited thereto.

Therefore, the first subpixel SP1 can display red R, the second subpixel SP2 can display green G, and the third subpixel SP3 can display blue B.

The red first subpixel SP1, the green second subpixel SP2, and the blue third subpixel SP3 can emit light of different colors, and to this end, the light-emitting elements 135 disposed in subpixels SP can have different emission layers. Since the emission layers for expressing different colors can have different efficiencies, the driving transistors of the subpixels SP for driving the emission layers can be given different required characteristics.

The display device 100 can further include a plurality of insulating layers 120 and a plurality of organic layers 140 disposed between electrodes constituting transistors T11, T12, T22, and T32 or between the transistors T11, T12, T22, and T32 and the light-emitting elements 135 on the substrate 111, and an encapsulating layer 150 disposed on the light-emitting elements 135.

The substrate 111 serves to support and protect components of the display device 100 disposed on the substrate 111. The substrate 111 can be formed of a flexible plastic material and thus have flexibility

In the active area AA, the substrate 111 can have a laminate of multiple layers, including a first flexible substrate 1111 and a second flexible substrate 1112 with an interlayer 117 interposed therebetween.

The first flexible substrate 1111 can form the lower surface of the substrate 111, and the second flexible substrate 1112 can form the upper surface of the substrate 111. For example, the first flexible substrate 1111 and the second flexible substrate 1112 can be made of polyimide but the embodiments of the present disclosure are not limited thereto.

The interlayer 117 can include an inorganic insulating material. For example, silicon nitride (SiNx) or silicon oxide (SiOx) can be used as an inorganic insulating material forming the interlayer 117, but the embodiments of the present disclosure are not limited thereto.

The first flexible substrate 1111 and the second flexible substrate 1112 are connected to each other via the interlayer 117. The interlayer 117 can be disposed in the entire active area AA between the first flexible substrate 1111 and the second flexible substrate 1112.

The plurality of insulating layers 120 can be disposed in a laminated manner in the active area AA of the substrate 111. The insulating layers 120 can include a first insulating layer 121, a second insulating layer 122, a third insulating layer 123, a fourth insulating layer 124, a fifth insulating layer 125, and a sixth insulating layer 126. One or more of the first insulating layer 121, the second insulating layer 122, the third insulating layer 123, the fourth insulating layer 124, the fifth insulating layer 125, and the sixth insulating layer 126 can be referred to as a gate insulating layer.

The first insulating layer 121 to the sixth insulating layer 126 are illustrated to describe the insulating relationship among active layers and electrodes constituting the transistors, which constitute the display device 100 of the present disclosure, and the number of insulating layers 120 on the substrate 111 is not limited thereto.

The first insulating layer 121 can be referred to as a buffer layer and can have the same function as a buffer layer known in the art. The first insulating layer 121 can be disposed on the substrate 111 to protect structures on the substrate 111 that are vulnerable to moisture penetration from moisture penetrating through the substrate 111 and can planarize the surface of the substrate 111.

The first insulating layer 121 can be a single inorganic layer or can be a laminate of multiple inorganic layers. For example, the first insulating layer 121 can include one or more of a silicon oxide (SiOx) layer, a silicon nitride (SiNx) layer, and a silicon oxynitride (SiOxNy) layer, or can include a laminate thereof, but the embodiments of the present disclosure are not limited thereto.

The second insulating layer 122 to the fourth insulating layer 124 are disposed on the first insulating layer 121. Each of the second insulating layer 122 to the fourth insulating layer 124 can include an inorganic layer, for example, a silicon oxide (SiOx) layer, a silicon nitride (SiNx) layer, or a laminate thereof, but the embodiments of the present disclosure are not limited thereto. The second insulating layer 122 can also serve as an interlayer insulating layer that insulates transistors that constitute a gate driver disposed in the non-active area NA. For example, the transistors constituting the gate driver can include an active layer including polysilicon, but the embodiments of the present disclosure are not limited thereto.

A switching transistor T11, a first driving transistor T12, a second driving transistor T22, and a third driving transistor 32 are disposed on the fourth insulating layer 124. A switching transistor as same as the switching transistor T11 may be provided at each of the second and third subpixels SP2 and SP3.

An active layer ACT11 of the switching transistor T11, a first active layer ACT12 of the first driving transistor T12, a second active layer ACT22 of the second driving transistor T22, and a third active layer ACT32 of the third driving transistor T32 are disposed the fourth insulating layer 124. The first active layer ACT12 of the first driving transistor T12, the second active layer ACT22 of the second driving transistor T22, and the third active layer ACT32 of the third driving transistor T32 are spaced apart from each other.

The active layer ACT11 of the switching transistor T11, the first active layer ACT12 of the first driving transistor T12, the second active layer ACT22 of the second driving transistor T22, and the third active layer ACT32 of the third driving transistor T32 can all be disposed on the same layer.

The active layer ACT11 of the switching transistor T11, the first active layer ACT12 of the first driving transistor T12, the second active layer ACT22 of the second driving transistor T22, and the third active layer ACT32 of the third driving transistor T32 can include the same material.

The active layer ACT11 of the switching transistor T11, the first active layer ACT12 of the first driving transistor T12, the second active layer ACT22 of the second driving transistor T22, and the third active layer ACT32 of the third driving transistor T32 can include an oxide semiconductor material.

The oxide semiconductor material can include at least one of, for example, an IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, or FIZO (FeInZnO)-based oxide semiconductor material, but the embodiments of the present disclosure are not limited thereto.

The first active layer ACT12 of the first driving transistor T12 and the third active layer ACT32 of the third driving transistor T32 include active spacers ASP in a region overlapping the gate electrodes G12 and G32 thereof.

The active spacer ASP refers to a space that separates two parts of the active layer adjacent to the space within the active layer, and the active spacer ASP can be a recess, a groove and/or a hole. In this instance, the active spacer ASP penetrates through the active layer ACT12 of the third driving transistor T12 and the third active layer ACT32 of the third driving transistor T32.

The fourth insulating layer 124 under the first active layer ACT12 can be exposed through the active spacer ASP in a region overlapping the gate electrode G12 of the first driving transistor T12. The fourth insulating layer 124 under the first active layer ACT12 of the first driving transistor T12 can be in contact with the fifth insulating layer 125 on the first active layer ACT12 through the active spacer ASP.

The fourth insulating layer 124 under the third active layer ACT32 can be exposed through the active spacer ASP in a region overlapping the gate electrode G32 of the third driving transistor T32. The fourth insulating layer 124 under the third active layer ACT32 of the third driving transistor T32 can be in contact with the fifth insulating layer 125 on the third active layer ACT32 through the active spacer ASP.

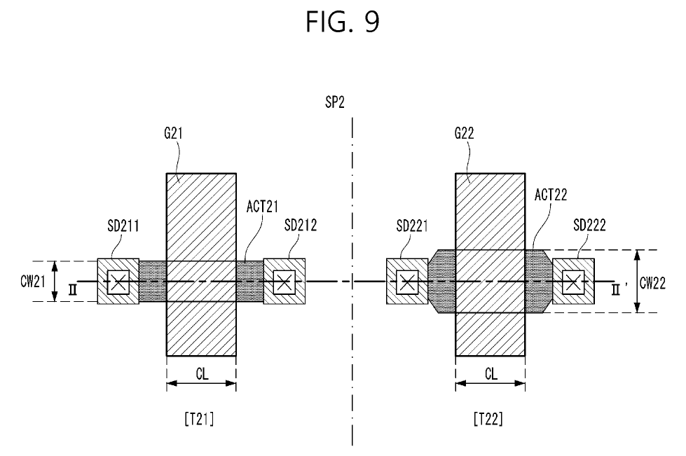

As shown in FIG. 9, in an embodiment, the second active layer ACT12 of the second driving transistor T22 of the second subpixel SP2 does not have an active spacer ASP in an area overlapping the gate electrode G22. In another embodiment, the second driving active layer ACT22 of the second driving transistor T22 can have an active spacer being a space that separates two parts of the second driving active layer ACT22 adjacent to the space in a region overlapping the second driving gate electrode G22. In this case, the number of active spacers ASP of the first driving transistor T12 of the first subpixel SP1 can be greater than the number of active spacers of the second active layer ACT12 of the second driving transistor T22 of the second subpixel SP2.

The number of active spacers ASP of the third active layer ACT32 of the third driving transistor T32 of the third subpixel SP3 is greater than the number of active spacers ASP of the first driving transistor T12 of the first subpixel SP1. The number of active spacers ASP of the third active layer ACT32 of the third driving transistor T32 of the third subpixel SP3 is greater than the number of active spacers ASP of the second driving transistor T22 of the second subpixel SP2.

The fifth insulating layer 125 is disposed on the active layers ACT11, ACT12, ACT22, and ACT32.

The fifth insulating layer 125 is positioned between the gate electrodes G11, G12, G22, and G32 and the active layers ACT11, ACT12, ACT22, and ACT32 to insulate the gate electrodes G11, G12, G22, and G32 and the active layers ACT11, ACT12, ACT22, and ACT32.

The fifth insulating layer 125 can include at least one of silicon oxide (SiOx), silicon nitride (SiNx), or silicon oxynitride (SiOxNy). For example, silicon oxide (SiO) can include silicon dioxide (SiO₂), but the embodiments of the present disclosure are not limited thereto.

The gate electrode G11 of the switching transistor T11, the gate electrode G12 of the first driving transistor T12, the gate electrode G22 of the second driving transistor T22, and the gate electrode G32 of the third driving transistor T32 are disposed on the fifth insulating layer 125.

The gate electrode G11 of the switching transistor T11, the gate electrode G12 of the first driving transistor T12, the gate electrode G22 of the second driving transistor T22, and the gate electrode G32 of the third driving transistor T32 are spaced apart from each other.

The gate electrode G11 of the switching transistor T11 is disposed to overlap at least partially with the active layer ACT11 of the switching transistor T11, and the gate electrode G12 of the first driving transistor T12 is disposed to overlap at least partially with the first active layer ACT12. The gate electrode G22 of the second driving transistor T22 is disposed to overlap at least partially with the second active layer ACT22, and the gate electrode G32 of the third driving transistor T32 is disposed to overlap at least partially with the third active layer ACT32.

The gate electrodes G11, G12, G22, and G32 include a conductive material. For example, the gate electrodes G11, G12, G22, and G32 can include metals such as aluminum (Al), chromium (Cr), copper (Cu), titanium (Ti), molybdenum (Mo), and tungsten (W), or can include a laminate thereof or an alloy thereof, but the embodiments of the present disclosure are not limited thereto.

The sixth insulating layer 126 is disposed on the gate electrodes G11, G12, G22, and G32.

The sixth insulating layer 126 is disposed to cover the fifth insulating layer 125 and the gate electrodes G11, G12, G22, and G32. The sixth insulating layer 126 can be referred to as an interlayer insulating layer and can serve as an interlayer insulating layer known in the relevant technical field.

The sixth insulating layer 126 can be an inorganic layer. The inorganic layer can include, for example, one or more of a silicon oxide (SiOx) layer, a silicon nitride (SiNx) layer, and a silicon oxynitride (SiOxNy) layer, or can include a laminate thereof, but the embodiments of the present disclosure are not limited thereto.

A plurality of first source-drain electrodes SD111, SD121, SD221, and SD321 and a plurality of second source-drain electrodes SD112, SD122, SD222, and SD322 are disposed on the sixth insulating layer 126. The first source-drain electrodes SD111, SD121, SD221, and SD321 and the second source-drain electrodes SD112, SD122, SD222, and SD322 can be spaced apart from each other.

The first source drain electrodes SD111, SD121, SD221, and SD321 and the second source drain electrodes SD112, SD122, SD222, and SD322 can include a conductive metal. The first source drain electrodes SD111, SD121, SD221, and SD321 and the second source drain electrodes SD112, SD122, SD222, and SD322 can include a metal such as aluminum (Al), titanium (Ti), copper (Cu), chromium (Cr), molybdenum (Mo), and tungsten (W) or an alloy thereof, or can include a laminate thereof.

The plurality of organic layers 140 are disposed on the first source-drain electrodes SD111, SD121, SD221, and SD321 and the second source-drain electrodes SD112, SD122, SD222, and SD322.

The plurality of organic layers 140 can be disposed on the transistors T11, T12, T22, and T32 or on the insulating layers 120 to protect the transistors T11, T12, T22, and T32 disposed on the substrate 111 and to alleviate step differences between the transistors T11, T12, T22, and T32 or the electrodes of the transistors T11, T12, T22, and T32. The organic layers 140 can cover the transistors T11, T12, T22, and T32 or can be disposed on the insulating layers 120 to provide a planarized surface.

The organic layers 140 can be disposed between the structures or elements of the transistors T11, T12, T22, and T32 and the light-emitting elements 135 to reduce parasitic capacitance occurring therebetween.

The organic layers 140 can be a single layer or multiple layers of organic materials. The organic layers 140 can include a first organic layer 141 and a second organic layer 142 on the first organic layer 141. In addition, the organic layers 140 can further include a third organic layer 143 on the second organic layer 142 that defines an emission area of the light-emitting element 135 which will be described below. The first to third organic layers 141, 142, and 143 can include the same material. The first to third organic layers 141, 142, and 143 can include different materials.

The first organic layer 141 covers electrodes of the transistors T11, T12, T22, and T32 in the active area AA to planarize the upper surface. The first organic layer 141 can include an organic material.

The organic material forming the first organic layer 141 can include one or more of acrylic resin, phenolic resin, polyimide resin, unsaturated polyester resin, polyamide resin, benzocyclobutene, polyphenylene resin, and polyphenylene sulfide resin.

The second organic layer 142 covers the transistors T11, T12, T22, and T32 and the first organic layer 141 in the active area AA to planarize the upper surface. The second organic layer 142 can include an organic material.

The organic material forming the second organic layer 142 can include one or more of acrylic resin, phenolic resin, polyimides resin, unsaturated polyesters resin, polyamides resin, benzocyclobutene, polyphenylene resin, and polyphenylene sulfide resin.

In addition to the insulating layers 120 described above, various functional organic layers or inorganic layers can be additionally disposed between the substrate 111 and the organic layers 140.

Upper metals CE2 can be disposed between the organic layers 140. Specifically, a plurality of upper metals CE2 can be disposed between the first organic layer 141 and the second organic layer 142. The upper metals CE2 are spaced apart from each other within one subpixel or between adjacent subpixels.

The upper metals CE2 can be disposed to overlap the active layer ACT11 of the switching transistor T11 of the subpixels SP1, SP2, and SP3. In addition, the upper metals CE2 can be disposed to overlap the first active layer ACT12 of the first driving transistor T12, the second active layer ACT22 of the second driving transistor T22, and the third active layer ACT32 of the third driving transistor T32 of the subpixels SP1, SP2, and SP3.

The upper metals CE2 can be disposed to overlap the active layers ACT11, ACT12, ACT22, and ACT32, thereby reducing the influence of light that can be incident on the active layers ACT11, ACT12, ACT22, and ACT32.

Some of the upper metals CE2 are electrically connected to the second source-drain electrodes of the transistors. In FIG. 5, some of the upper metals CE2 are connected to the first driving transistor T12, the second driving transistor T22, and the third driving transistor T32 of the subpixels SP1, SP2, and SP3, but this is to indicate that the driving transistors are electrically connected to supply a driving current to the light-emitting element 135, and the connection relationship of FIG. 5 is not limited to physical contact.

For example, a transistor connected to some of the upper metals CE2 can be the second transistor T2 having a driving transistor function, as illustrated in FIG. 3. Alternatively, a transistor connected to some of the upper metals CE2 can be the fourth transistor T4 having a light-emitting transistor function, as illustrated in FIG. 4, but the embodiments of the present disclosure are not limited thereto.

When the upper metals CE2 are individually connected to the second source-drain electrodes SD122, SD222, and SD322, the upper metals CE2 can serve as connecting electrodes. When the upper metals CE2 serve as connecting electrodes, one end of each upper metal CE2 is electrically connected to the first electrode E1 of the light-emitting element 135 of each of the subpixels SP1, SP2, and SP3.

The second source-drain electrode SD122 of the first driving transistor T12 and the first electrode E1 of the light-emitting element 135 can be electrically connected to each other through the upper metal CE2 as a connecting electrode, and thus current can be supplied to the light-emitting element 135 of the first subpixel SP1.

The second source-drain electrode SD222 of the second driving transistor T22 and the first electrode E1 of the light-emitting element 135 can be electrically connected to each other through the upper metal CE2 as a connecting electrode, and thus current can be supplied to the light-emitting element 135 of the second subpixel SP2.

The second source-drain electrode SD322 of the third driving transistor T32 and the first electrode E1 of the light-emitting element 135 can be electrically connected to each other through the upper metal CE2 as a connecting electrode, and thus current can be supplied to the light-emitting element 135 of the third subpixel SP3.

The upper metals CE2 can include a conductive material. For example, the upper metals CE2 can include a metal such as aluminum (Al), chromium (Cr), copper (Cu), titanium (Ti), molybdenum (Mo), and tungsten (W). The upper metals CE2 can include a multilayer structure in which metals such as aluminum (Al), chromium (Cr), copper (Cu), titanium (Ti), molybdenum (Mo), and tungsten (W) are laminated, an alloy of these metals, or a laminate of alloys, but the embodiments of the present disclosure are not limited thereto.

The light-emitting element 135 is disposed on the plurality of organic layers 140. The light-emitting element 135 can be electrically connected to the individual driving transistors T12, T22, and T32 of the subpixels SP1, SP2, and SP3. The light-emitting element 135 includes the first electrode E1, an emission layer EL, and a second electrode E2.

The first electrode E1 can serve as an anode. The first electrode E1 can include a metal material having high reflectivity. When the display device 100 is a top-emitting type, the first electrode E1 can be referred to as a reflective electrode.

For example, the first electrode E1 can be formed as a multilayer structure such as a laminate (Ti/Al/Ti) of aluminum (Al) and titanium (Ti), a laminate (ITO/Al/ITO) of aluminum (Al) and ITO, an APC (Ag/Pd/Cu) alloy, a laminate (ITO/APC/ITO) of an APC alloy and ITO, or a laminate (Ag/MoTi) of silver (Ag) and molybdenum/titanium alloy, or can include a single layer structure made of one material selected from silver (Ag), aluminum (Al), molybdenum (Mo), gold (Au), magnesium (Mg), calcium (Ca), and barium (Ba), or two or more alloy materials, but the embodiments of the present disclosure are not limited thereto.

The emission layer EL is provided on the first electrode E1. The emission layer EL can include a hole injection layer, a hole transport layer, an organic emission layer, an electron transport layer, and an electron injection layer.

In the drawing, the emission layer EL is disposed in an opening, but the hole injection layer, the hole transport layer, the electron transport layer, and the electron injection layer that constitute the emission layer EL can be disposed commonly on the entire surface of the active area AA.

The emission layer EL can include at least one of a red emission layer that emits red light, a green emission layer that emits green light, a blue emission layer that emits blue light, or an emission layer including a laminate thereof. The emission layer EL can be provided on the first electrode E1 for each subpixel SP.

The emission layer EL can be a white emission layer that emits white light. In this case, the emission layer EL can be a common layer that is commonly disposed in the subpixels SP1, SP2, and SP3 rather than in a patterned form.

As described above, the emission layer EL can be disposed in a tandem structure of two or more stacks. In this case, the light-emitting element 135 can include a charge generation layer disposed between the stacks. The charge generation layer can be a common layer disposed on the overall surface of the active area AA.

The second electrode E2 is provided on the emission layer EL. The second electrode E2 can serve as a cathode. The second electrode E2 can be commonly disposed in the entire area of the active area AA as well as the emission areas of the subpixels SP1, SP2, and SP3 (refer to EA1, EA2, and EA3 in FIG. 2).

The second electrode E2 can be a common layer for applying the same voltage to the subpixels SP1, SP2, and SP3. To this end, the second electrode E2 can extend from the active area AA to a part of the non-active area NA.

If the active area AA is functionally divided, the second electrode E2 can be disposed in a pattern form. For example, if the active area AA is functionally divided into an area where a camera is installed, an area where a sensor is installed, and a transmissive area, the second electrode E2 may not be disposed in the transmissive area.

The second electrode E2 can be a light-transmitting electrode. The second electrode E2 can include a transparent conductive material (TCO) such as ITO or IZO that can transmit light, or a semi-transmissive conductive material such as magnesium (Mg), silver (Ag), or an alloy of magnesium (Mg) and silver (Ag). The second electrode E2 can have a multilayer structure in which some of ITO, IZO, Mg, and Ag are laminated, and can include an alloy of these materials or a multilayer structure in which alloys are laminated, but the embodiments of the present disclosure are not limited thereto. When the second electrode E2 includes a semi-transmissive conductive material, the luminous efficacy can be improved through the microcavity effect.

A front emission type (top emission) have been described as an example of the light-emitting element 135. However, the light-emitting element 135 of the present disclosure is not limited thereto, and can be a back emission type in which light from the emission layer EL is emitted toward the substrate 111. In this case, the first electrode E1 can be made of a transparent or translucent electrode material, and the second electrode E2 can be made of a reflective electrode material. The materials described above can be used as transparent and translucent electrode materials and a reflective electrode material.

The third organic layer 143 can be disposed on the second organic layer 142 to cover the end of the first electrode E1 of the light-emitting element 135. The third organic layer 143 can be referred to as a bank that defines an emission area.

The third organic layer 143 is disposed to expose the first electrode E1 of the emission area for emission areas (EA1, EA2, and EA3 in FIG. 2) such that the first electrodes E1 can be electrically insulated between adjacent subpixels SP1, SP2, and SP3. By using a halftone mask, the third organic layer 143 can be provided in a form having spacers between banks as well as the banks. The spacers can serve to support a deposition mask such that the deposition mask does not come into contact with the banks and the structures below the banks when the emission layer EL is formed.

The third organic layer 143 can extend from the active area AA to a part of the non-active area NA. The third organic layer 143 can be patterned according to a functional role in the non-active area NA.

The third organic layer 143 can include a different material from the first organic layer 141 or the second organic layer 142. The third organic layer 143 can include one organic material selected from among polyimide resin, acrylic resin, epoxy resin, phenolic resin, and polyamide resin.

The encapsulation layer 150 is disposed on the light-emitting element 135. The encapsulation layer 150 extends from the active area AA and is also disposed on the non-active area NA. The encapsulation layer 150 can cover the active area AA and the non-active area NA to prevent oxygen or moisture from penetrating into structures on the substrate 111, such as the light-emitting element 135 and transistors. If necessary, other layers, such as a capping layer, can be additionally interposed between the encapsulation layer 150 and the second electrode E2.

The encapsulation layer 150 can be composed of a plurality of layers. The encapsulation layer 150 can have a structure in which inorganic layers and organic layers are alternately laminated.

The encapsulation layer 150 can be disposed over the transistors T11, T12, T22, and T32 and the light-emitting element 135 in the active area AA. The encapsulation layer 150 can completely cover the light-emitting element 135 to seal the light-emitting element 135. The encapsulation layer 150 can extend from the active area AA to a part of the non-active area NA.

Inorganic layers constituting the encapsulation layer 150 can include silicon oxide, silicon nitride, and/or silicon oxynitride.

Organic layers constituting the encapsulation layer 150 can include one or more organic materials selected from the group consisting of polyethylene terephthalate, polyethylene naphthalate, polycarbonate, polyimide, polyethylene sulfonate, polyoxymethylene, polyarylate, and hexamethyldisiloxane, but embodiments of the present disclosure are not limited thereto.

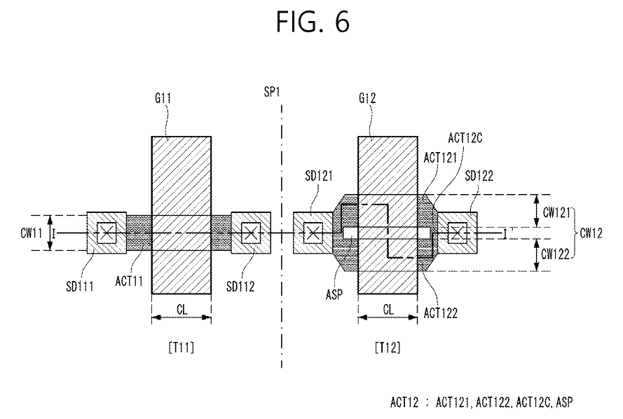

Hereinafter, switching transistors T11, T21, and T31 and driving transistors T12, T22, and T32 of the subpixels SP1, SP2, and SP3 according to the embodiments of the present disclosure will be described in detail with reference to FIG. 6 to FIG. 12.

However, redundant description with respect to the transistors according to the embodiments described with reference to FIG. 1 to FIG. 5 above can be omitted. The components denoted by the same drawing symbols described with reference to FIG. 1 to FIG. 5 can be applied in the same manner in other embodiments of the present disclosure, or can be applied in embodiments combined with other embodiments.

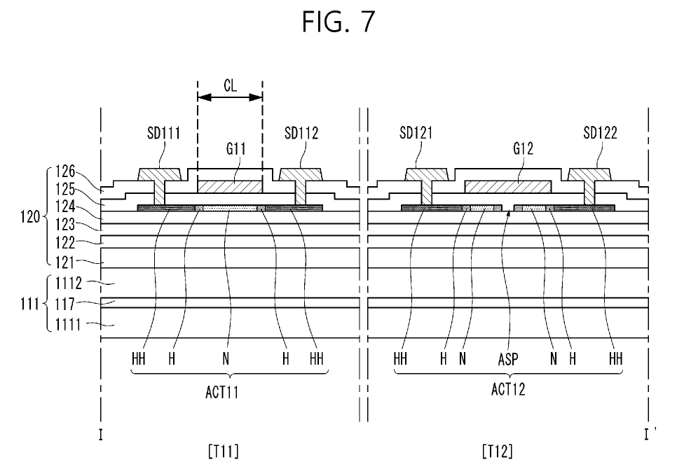

Referring to FIG. 6 and FIG. 7, the first subpixel SP1 emits light of a first wavelength, and the first wavelength can be longer than a second wavelength emitted from the second subpixel SP2 and longer than a third wavelength emitted from the third subpixel SP3. The first subpixel SP1 can display red. The first wavelength can be in a red wavelength range. The first wavelength can be in a range of 590 nm to 700 nm.

The switching transistor T11 of the first subpixel SP1 has a gate electrode G11, a channel region CL and CW11 overlapping the gate electrode G11, an active layer ACT11 including an oxide semiconductor material, a first source-drain electrode SD111, and a second source-drain electrode SD112. The channel region CL and CW11 of the switching transistor T11 can be defined by a channel length CL and a channel width CW11.

The oxide semiconductor material forming the active layer ACT11 of the switching transistor T11 can include at least one of, for example, an IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, or FIZO (FeInZnO)-based oxide semiconductor material, but the embodiments of the present disclosure are not limited thereto.

The active layer ACT11 of the switching transistor T11 includes a conductive region HH, a normal region N, and a high-mobility region H having a higher mobility than the mobility of the normal region N. In the present disclosure, low mobility and high mobility are relative concepts, and by comparing the magnitudes of mobilities, relatively low mobility can be referred to as low mobility or normal mobility, and relatively high mobility can be referred to as high mobility.

The conductive region HH of the active layer ACT11 is a crystallized region connected to or in contact with the source and drain electrodes SD111 and SD112 without overlapping the gate electrode G11.

The normal region N of the active layer ACT11 overlaps the gate electrode G11 and generally forms a channel, and has lower mobility than the mobility of the conductive region HH.

The high-mobility region H of the active layer ACT11 is a region having higher mobility than the mobility of the normal region N and lower mobility than the mobility of the conductive region HH. The high-mobility region H of the active layer ACT11 can be disposed on both sides of the normal region N.

The high-mobility region H of the active layer ACT11 of the switching transistor T11 overlaps the edge of the gate electrode G11 and can be disposed between the normal region N and the conductive region HH.

The first driving transistor T12 of the first subpixel SP1 includes a gate electrode G12, a channel region CL and CW12 overlapping the gate electrode G12, a first active layer ACT12 including an oxide semiconductor material, a first source-drain electrode SD121, and a second source-drain electrode SD122. The channel region CL and CW12 of the first driving transistor T12 can be defined by a channel length CL, a first channel width CW121, and a second channel width CW122. The first driving channel width CW121 and the second driving channel width CW122 can be collectively referred to as a first channel width CW12.

The oxide semiconductor material forming the first active layer ACT12 of the first driving transistor T12 can be the same as the active layer ACT11 of the switching transistor T11.

The first active layer ACT12 of the first driving transistor T12 of the first subpixel SP1 has an active spacer ASP where the first active layer ACT12 is separated in a region overlapping with the gate electrode G12 of the first driving transistor T12.

The active spacer ASP does not overlap with the first source-drain electrode SD121 and the second source-drain electrode SD122 of the first driving transistor T12 and is disposed parallel to the direction of the channel length CL of the first active layer ACT12.

The active spacer ASP extends in both directions from the region overlapping the gate electrode G12 of the first driving transistor T12 toward the first source-drain electrode SD121 and the second source-drain electrode SD122, and protrudes from the edge of the gate electrode G12 to have a region that does not overlap with the gate electrode G12.

The active spacer ASP extends parallel to the channel length CL of the first active layer ACT12, and the region of the active spacer ASP of the first active layer ACT12 overlapping with the gate electrode G12 and the region of the active spacer ASP that does not overlap with the gate electrode G12 are formed as one body.

The size of the region of the active spacer ASP overlapping with the gate electrode G12 of the first driving transistor T12 can be greater than the size of the region of the active spacer ASP that does not overlap with the gate electrode G12 of the first driving transistor T12.

When a direction parallel to an imaginary line crossing the first source-drain electrode SD121 and the second source-drain electrode SD122 of the first driving transistor T12 is referred to as a first direction, and a direction perpendicular to the first direction is referred to as a second direction, the length of the active spacer ASP disposed in the first direction is greater than the length of the active spacer ASP disposed in the second direction.

Here, the first direction can be a direction parallel to the channel length CL, and the second direction can be a direction parallel to the channel width CW11 and CW12.

The first active layer ACT12 includes a first region ACT121 and a second region ACT122 spaced apart from each other in the second direction with the active spacer ASP interposed therebetween, and an active connection portion ACT12C connecting the first region ACT121 and the second region ACT122 without overlapping with the gate electrode G12 of the first driving transistor T12.

The first region ACT121 has a first channel width CW121 in the region overlapping with the gate electrode G12, and the second region ACT122 has a second channel width CW122 in the region overlapping with the gate electrode G12. Both the first region ACT121 and the second region ACT122 can have the channel length CL in the region overlapping with the gate electrode G12.

The first driving transistor T12 has the first channel width CW121 and the second channel width CW122 according to the active spacer ASP, and can have the channel length CL for the first channel width CW121 and the channel length CL for the second channel width CW121. The first driving transistor T12 can have two channels separated by the active spacer ASP.

The active connection portion ACT12C does not overlap with the gate electrode G12 and can include a region where the first active layer ACT12 and the first source-drain electrode SD121 and the second source-drain electrode SD122 are connected across the active spacer ASP.

The first active layer ACT12 of the first driving transistor T12 includes a conductive region HH, a normal region N, and a high-mobility region H having a higher mobility than the mobility of the normal region N. The concepts of high mobility and low mobility in the present disclosure should be understood as relative concepts.

The conductive region HH of the first driving transistor T12 is a crystalline region of the first active layer ACT12 that does not overlap with the gate electrode G12 and is connected to or in contact with the source-drain electrodes SD121 and SD122. The conductive region HH of the first active layer ACT12 is located in a region that does not overlap with the gate electrode G12.

The normal region N of the first driving transistor T12 overlaps with the gate electrode G12 and is a region into which ions for crystallization of the conductive region HH are not injected. The normal region N of the first driving transistor T12 overlaps with the gate electrode G12 and generally forms a channel, and has a lower mobility than the mobility of the conductive region HH.

According to an embodiment of the present disclosure, the normal region N of the first driving transistor T12 of the first subpixel SP1 is separated by the active spacer ASP.

The first active layer ACT12 of the first driving transistor T12 includes the high-mobility region H. The high-mobility region H refers to a region having higher mobility than the mobility of the normal region N and lower mobility than the mobility of the conductive region HH.

The high-mobility region H can be formed by ions of the conductive region HH diffusing toward the normal region N, ions of an etchant used in a patterning process performed during a process being injected into the exposed active layer, or by doping with ions during an annealing process.

The high-mobility region H of the first active layer ACT12 can be disposed on both sides of the normal region N between the normal region N and the conductive region HH. In addition, the high-mobility region H of the first active layer ACT12 can be further disposed at the edge of the first active layer ACT12 exposed by the active spacer ASP.

Accordingly, the high-mobility region H of the first active layer ACT12 overlaps with the edge of the gate electrode G12, is in contact with the normal region N, and is disposed between the normal region N and the conductive region HH. In addition, the high-mobility region H of the first active layer ACT12 can be disposed at the edge of the normal region N separated by the active spacer ASP. The high-mobility region H of the first active layer ACT12 can overlap with the center portion of the gate electrode G12 of the first driving transistor T12 and can be disposed at the edges of the first region ACT121 and the second region ACT122 of the first active layer ACT12 which are in contact with the active spacer ASP.

The connection portion ACT12C of the first active layer ACT12 is disposed on both sides (based on the first direction) of the active spacer ASP and includes the conductive region HH and the high-mobility region H.

The active connection portion ACT12C of the first active layer ACT12 is disposed in a region that does not overlap with the gate electrode G12 of the first driving transistor T12 and includes the conductive region H and the high-mobility region H, and thus the mobility of the active connection portion ACT12C of the first active layer ACT12 can be greater than the mobility of the first region ACT121 and the second region ACT122. In addition, the conductivity of the active connection portion ACT12C of the first active layer ACT12 can be greater than the conductivity of the first region ACT121 and the second region ACT122.

In the region where the gate electrode G12 of the first driving transistor T12 and the first active layer ACT12 overlap, the edge of the first region ACT121 of the first active layer ACT12 can become a high-mobility region H, and the center of the first region ACT121 can become a normal region N.

Accordingly, in the region where the gate electrode G12 of the first driving transistor T12 and the first active layer ACT12 overlap, the mobility of the edge of the first region ACT121 of the first active layer ACT12 can be greater than the mobility of the center of the first region ACT121. In addition, the conductivity of the edge of the first region ACT121 of the first active layer ACT12 can be greater than the conductivity of the center of the first region ACT121. In the region where the gate electrode G12 of the first driving transistor T12 and the first active layer ACT12 overlap, the edge of the second region ACT122 of the first active layer ACT12 can become a high-mobility region H, and the center of the second region ACT122 can become a normal region N. Therefore, in the region where the gate electrode G12 of the first driving transistor T12 and the first active layer ACT12 overlap, the mobility of the edge of the second region ACT122 of the first active layer ACT12 can be greater than the mobility of the center of the second region ACT122. In addition, the conductivity of the edge of the second region ACT122 of the first active layer ACT12 can be greater than the conductivity of the center of the second region ACT122.

A part of the first region ACT121 in contact with the edge of the active spacer ASP of the first active layer ACT12 can be exposed during the process and thus can become a high-mobility region H. Therefore, the mobility of the first region ACT121 in contact with the edge of the active spacer ASP of the first active layer ACT12 can be greater than the mobility of the first region ACT121 away from the edge of the active spacer ASP. In addition, the conductivity of the first region ACT121 in contact with the edge of the active spacer ASP can be greater than the conductivity of the first region ACT121 away from the edge of the active spacer ASP.

A part of the second region ACT122 in contact with the edge of the active spacer ASP of the first active layer ACT12 can be exposed during the process and thus can become a high-mobility region H. Therefore, the mobility of the second region ACT122 in contact with the edge of the active spacer ASP of the first active layer ACT12 can be greater than the mobility of the second region ACT122 away from the edge of the active spacer ASP. In addition, the conductivity of the second region ACT122 in contact with the edge of the active spacer ASP can be greater than the conductivity of the second region ACT122 away from the edge of the active spacer ASP.

The mobility regions of the first active layer ACT12 can be disposed in the order of the conductive region HH, the high-mobility region H, the normal region N, the high-mobility region H, and the conductive region HH in the first direction in the first region ACT121. The mobility regions of the first active layer ACT12 can be disposed in the order of the conductive region HH, the high-mobility region H, the normal region N, the high-mobility region H, and the conductive region HH in the first direction in the second region ACT122.

In the region overlapping the gate electrode G12 in the second direction, the mobility regions of the first active layer ACT12 can be disposed in the order of the high-mobility region H, the normal region N, the high-mobility region H, the active spacer ASP, the high-mobility region H, the normal region N, and the high-mobility region H.

As described above, the first active layer ACT12 of the first driving transistor T12 of the first subpixel SP1 according to an embodiment of the present disclosure includes the active spacer ASP, and the first active layer ACT12 can have a plurality of high-mobility regions H in the direction of the channel length CL in the channel region through the active spacer ASP.

According to an embodiment of the present disclosure, the first driving transistor T12 of the first subpixel SP1 can lower the resistance value through the plurality of high-mobility regions H disposed in the first active layer ACT12, and thus increase the current. When the first subpixel SP1 has lower luminous efficacy than the second subpixel SP2, a greater amount of current is required for the first subpixel SP1. However, the first driving transistor T12 of the first subpixel SP1 can have a greater number of high-mobility regions than the second subpixel SP2 by including the active spacer ASP, and thus can increase the amount of current, thereby improving the luminance and achieving characteristics required for the first subpixel SP1.

In addition, the first driving transistor T12 of the first subpixel SP1 according to an embodiment of the present disclosure can increase ON current, and thus the threshold voltage of the first driving transistor T12 can be reduced, stress of the first driving transistor T12 can be decreased, deterioration of the first driving transistor T12 can be prevented, and power consumption can be reduced.

In the case of a transistor having an active layer including an oxide semiconductor material, the transistor can be subjected to positive bias thermal stress (PBTS) when the active layer deteriorates during long-term driving or in a high-temperature environment, and the threshold voltage Vth can shift in the (+) direction due to the PBTS.

However, in the case of the first driving transistor T12 of the first subpixel SP1 according to the present disclosure, the high-mobility region H is disposed at the edge of the first active layer ACT12 exposed through the active spacer ASP in the region overlapping the first active layer ACT12 and the gate electrode G12, and thus the degree of deterioration of the first driving transistor T12 can be decreased even when the first driving transistor T12 is driven for a long time or in a high-temperature environment.

Therefore, the display device 100 according to the present disclosure can stabilize the PBTS characteristic of the first driving transistor T12 of the first subpixel SP1 to provide a driving transistor with small variation in the threshold voltage and improve reliability.

In addition, according to an embodiment of the present disclosure, the first driving transistor T12 of the first subpixel SP1 has one first active layer ACT12 having different mobilities by having the active spacer ASP instead of having active layers having different mobilities formed through a separate process.

Since the active spacer ASP of the first sub-pixel SP1 can be formed without performing a separate additional process, the display device 100 according to an embodiment of the present disclosure can reduce production energy and reduce greenhouse gas emissions that can occur due to the manufacturing process through process optimization, thereby achieving ESG (Environmental/Social/Governance).

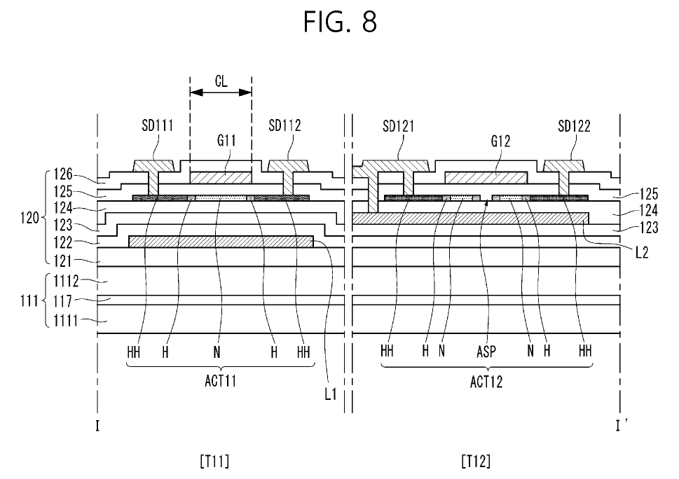

As illustrated in FIG. 8, the switching transistor T11 can further include a first lower metal L1 under the active layer A11.

The first lower metal L1 can be disposed between the first insulating layer 121 and the second insulating layer 122. The second insulating layer 122, the third insulating layer 123, and the fourth insulating layer 124 can be further disposed between the first lower metal L1 and the active layer ACT11 of the switching transistor T11.

The first lower metal L1 can be electrically connected to the gate electrode G11 of the switching transistor T11. Since the first lower metal L1 is electrically connected to the gate electrode G11 of the switching transistor T11, when a turn-on voltage is applied to the gate electrode G11 of the switching transistor T11, the electric field applied to the active layer ACT11 of the switching transistor T11 can be strengthened, thereby improving the turn-on characteristics of the switching transistor T11.

Accordingly, the switching transistor T11 according to the present embodiment can generate a high driving current, and the channel region of the active layer ACT11 can be rapidly controlled.

The first lower metal L1 can include a conductive material, and can include, for example, a metal such as aluminum (Al), titanium (Ti), copper (Cu), chromium (Cr), molybdenum (Mo), and tungsten (W), an alloy thereof, a laminate thereof, or a laminate of alloys thereof, but the embodiments of the present disclosure are not limited thereto.

The first lower metal L1 can include a different metal material from the gate electrode G11 of the switching transistor T11. The first lower metal L1 can be disposed in a different layer from a second lower metal L2 and can include a different material from the second lower metal L2.

The second insulating layer 123 and the third insulating layer 123 can be disposed between the first lower metal L1 and the second lower metal L2.

The first driving transistor T12 can further include the second lower metal L2 under the first active layer ACT12.

The second lower metal L2 can be disposed between the third insulating layer 123 and the fourth insulating layer 124. The fourth insulating layer 124 can be further disposed between the second lower metal L2 and the first active layer ACT12 of the first driving transistor T12.

The second lower metal L2 can be electrically connected to the first source drain electrode SD121 of the first driving transistor T12. At this time, the first driving transistor T12 can block light through the second lower metal L2 to minimize the influence of light on the first active layer ACT12 of the first driving transistor T12.

In addition, when the second lower metal L2 is electrically connected to the first source drain electrode SD121 of the first driving transistor T12, the ON current value of the first driving transistor T12 can be increased.

The first driving transistor T12 can be electrically connected to the light-emitting element 135 through the third transistor T3 illustrated in FIG. 4. The display device 100 according to the present disclosure can increase the ON current value by electrically connecting the second lower metal L2 of the first driving transistor T12 and the first source-drain electrode SD121 of the first driving transistor T12, and thus the concentration of carriers moving when the first driving transistor T12 is turned on relatively increases, and thus the current can further increase, and the luminance of light emitted from the light-emitting element 135 can be further improved.

The second lower metal L2 can include a conductive material, and can include, for example, a metal such as aluminum (Al), titanium (Ti), copper (Cu), chromium (Cr), molybdenum (Mo), and tungsten (W), or an alloy thereof, a laminate thereof, or a laminate of alloys thereof but the embodiments of the present disclosure are not limited thereto.

The second lower metal L2 is disposed in a different layer from the first lower metal L1 connected to the switching transistor T11.

With references to FIGS. 7 and 8, in view of FIGS. 5 and 6, each of the conductive region HH, the normal region N, the high-mobility region H, and the active spacer ASP can have lengths in the second direction in FIG. 6. Accordingly, FIGS. 7 and 8 show that the arrangement of the active layer ACT11 of the switching transistor T11 which shows a sequence of the conductive region HH, the high-mobility region H, the normal region N, the high-mobility region H and the conductive region HH from the first source-drain electrode SD111 to the second source-drain electrode SD112. Meanwhile, the arrangement of the first active layer ACT12 of the first driving transistor T12 shows a sequence of the conductive region HH, the high-mobility region H, the normal region N, the high-mobility region H, the active spacer ASP, the high-mobility region H, the normal region N, the high-mobility region H and the conductive region HH from the first source-drain electrode SD121 to the second source-drain electrode SD122. Thus, the conductive region HH, the high-mobility region H, the normal region N and/or the active spacer ASP in the switching transistor T11 and the first driving transistor T12 generally extend in the second direction, which is the same direction as a longitudinal direction of the gate electrodes G11 and G12. It is also noted that the cross-sectional view of the first active layer ACT12 of the first driving transistor T12 in FIGS. 7 and 8 are provided by a square wave portion of the line I-I’ in FIG. 6. In this regard, referring to the vertical section of the line I-I’ in FIG. 6 for first driving transistor T12, which is depicted in cross-sectional view in FIGS. 7 and 8, the pair of high-mobility regions H on opposite sides of the active spacer ASP can be portions of the high-mobility region H that extend in the first direction that is intersecting the second direction. Thus, the portion (i.e., a first portion) of the high-mobility region H that is immediately adjacent to the active spacer ASP extends in a direction different from the portion (i.e., a second portion) of the high-mobility region H that is immediately adjacent the conductive region HH in the first driving transistor T12. In this regard, the first portion of the high-mobility region H extends in the first direction and the second portion of the high-mobility region H extends in the second direction. Also, the first and second portions of the high-mobility region H can be in contact or be connected, but such is not required, so that the first and second portions of the high-mobility region H can be disconnected or not in contact. In embodiments of the present disclosure, widths of the first and second portions of the high-mobility region H can be the same or different. For example, the width of the first portion of the high-mobility region H can be smaller or greater than the width of the second portion of the high-mobility region H.

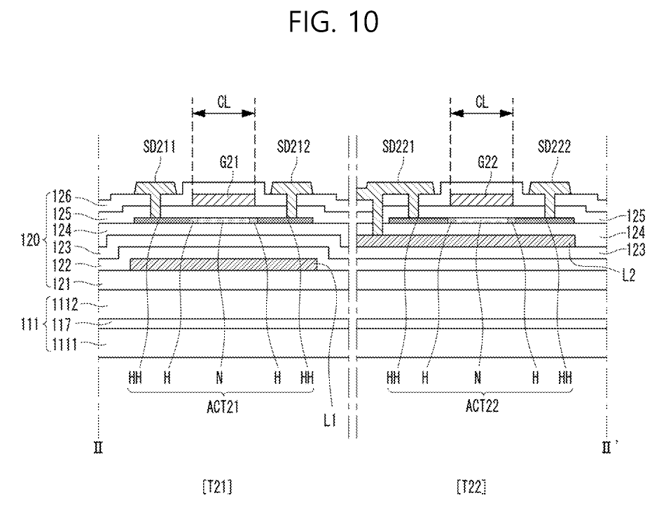

Referring to FIG. 9 and FIG. 10, the second subpixel SP2 emits light of the second wavelength, and the second wavelength can be longer than the first wavelength emitted from the first subpixel SP1 and the third wavelength emitted from the third subpixel SP3. The second subpixel SP2 can display green. The second wavelength can be in a green wavelength range. The second wavelength can be in a range of 495 nm to 5700 nm.

The switching transistor T21 of the second subpixel SP2 includes a gate electrode G21, a channel region CL and CW21 overlapping the gate electrode G21, an active layer ACT21 including an oxide semiconductor material, a first source-drain electrode SD211, and a second source-drain electrode SD212. The channel region CL and CW21 of the switching transistor T21 can be defined by the channel length CL and the channel width CW21.

The oxide semiconductor material forming the active layer ACT21 of the switching transistor T21 can include at least one of, for example, an IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, or FIZO (FeInZnO)-based oxide semiconductor material, but the embodiments of the present disclosure are not limited thereto.

The active layer ACT21 of the switching transistor T21 includes a conductive region HH, a normal region N, and a high-mobility region H having a higher mobility than the mobility of the normal region N.

The conductive region HH of the active layer ACT21 is a region that does not overlap with the gate electrode G21 and is connected to or in contact with the source-drain electrodes SD211 and SD212.

The normal region N of the active layer ACT21 overlaps with the gate electrode G21, generally forms a channel, and has lower mobility than the mobility of the conductive region HH.

The high-mobility region H of the active layer ACT21 has higher mobility than the mobility of the normal region N and lower mobility than the mobility of the conductive region HH. The high-mobility region H of the active layer ACT21 can be disposed on both sides of the normal region N.

The high-mobility region H of the active layer ACT21 of the switching transistor T21 overlaps with the edge of the gate electrode G21 and can be disposed between the normal region N and the conductive region HH.

The second driving transistor T22 of the second subpixel SP2 includes a gate electrode G22, a channel region CL and CW22 overlapping the gate electrode G22, a second active layer ACT22 including an oxide semiconductor material, a first source-drain electrode SD221, and a second source-drain electrode SD222. The channel region CL and CW22 of the second driving transistor T22 can be defined by a channel length CL and a channel width CW22.

The oxide semiconductor material forming the second active layer ACT22 of the second driving transistor T22 can be the same as the oxide semiconductor material forming the active layer ACT21 of the switching transistor T21 of the second subpixel SP2, or can be the same as the oxide semiconductor material forming the active layer ACT11 of the switching transistor T11 of the first subpixel SP1 or the first active layer ACT12 of the first driving transistor T12.

Unlike the first active layer ACT12 of the first driving transistor T12 of the first subpixel SP1, the second active layer ACT22 of the second driving transistor T22 of the second subpixel SP2 does not have an active spacer ASP.

The second active layer ACT22 has a channel length CL in the first direction in the region overlapping the gate electrode G22 and a channel width CW22 in the second direction.

The second active layer ACT22 of the second driving transistor T22 includes a conductive region HH, a normal region N, and a high-mobility region H having higher mobility than the mobility of the normal region N. The concepts of high mobility and low mobility in the present disclosure should be understood as relative concepts as described above.

The conductive region HH of the second driving transistor T22 is a region of the second active layer ACT22 that does not overlap with the gate electrode G22 and is connected to or in contact with the source-drain electrodes SD221 and SD222. The conductive region HH of the second active layer ACT22 is located in a region that does not overlap with the gate electrode G22.

The normal region N of the second driving transistor T22 overlaps with the gate electrode G22 and is a region where ions for crystallization of the conductive region HH are not injected. The normal region N of the second driving transistor T22 overlaps with the gate electrode G22, generally forms a channel, and has lower mobility than the mobility of the conductive region HH.

The second active layer ACT22 of the second driving transistor T22 includes the high-mobility region H. The high-mobility region H can have higher mobility than the mobility of the normal region N and lower mobility than the mobility of the conductive region HH.

The high-mobility region H can be formed by ions of the conductive region HH diffusing toward the normal region N, by ions being injected into the exposed active layer by an etchant used in a patterning process performed during a process, or by doping with ions during an annealing process. The high-mobility region H of the second active layer ACT22 can be disposed on both sides of the normal region N between the normal region N and the conductive region HH. In addition, the high-mobility region H of the second active layer ACT22 can be further disposed at the edge of the first active layer ACT12 exposed through the active spacer ASP.

Therefore, the high-mobility region H of the second active layer ACT22 overlaps with the edge of the gate electrode G22, and can be in contact with the normal region N and disposed between the normal region N and the conductive region HH. The mobility regions of the second active layer ACT22 can be disposed in the order of the conductive region HH, the high-mobility region H, the normal region N, the high-mobility region H, and the conductive region HH in the first direction.

In the region overlapping the gate electrode G22 in the second direction, the mobility regions of the second active layer ACT22 can be disposed in the order of the high-mobility region H, the normal region N, the high-mobility region H, the high-mobility region H, the normal region N, and the high-mobility region H.

As described above, the second active layer ACT22 of the second driving transistor T22 of the second subpixel SP2 according to an embodiment of the present disclosure does not have an active spacer ASP, and thus the S factor can be increased. Accordingly, it is possible to improve the grayscale expression of the second subpixel SP2 according to the S factor increase.

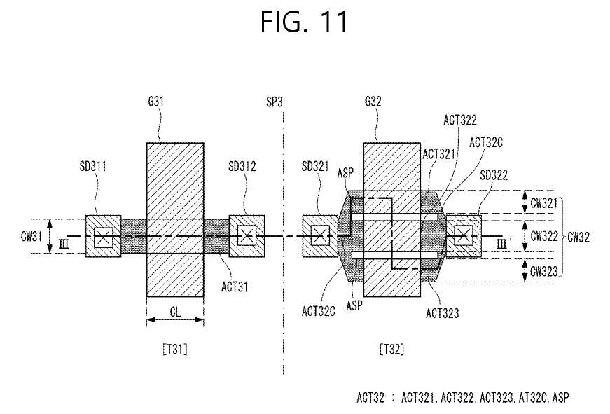

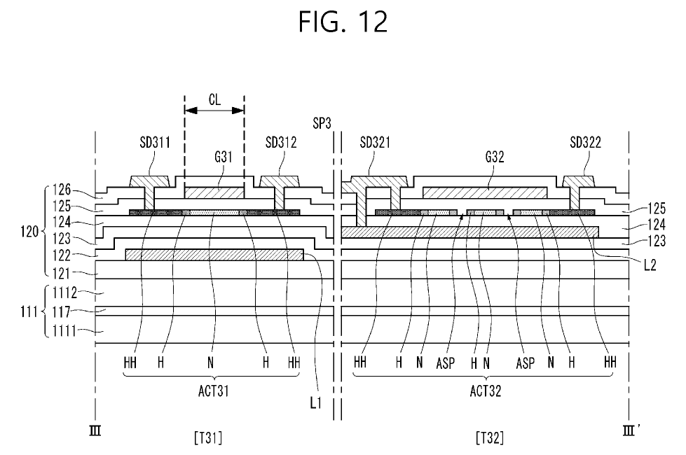

Referring to FIG. 11 and FIG. 12, the third subpixel SP3 emits light of the third wavelength, and the third wavelength can be shorter than the second wavelength emitted from the second subpixel SP2 and the first wavelength emitted from the first subpixel SP1. The third subpixel SP3 can display blue. The third wavelength can be in a blue wavelength range. The third wavelength can be in a range of 430 nm to 498 nm.

The switching transistor T31 of the third subpixel SP3 includes a gate electrode G31, a channel region CL and CW31 overlapping the gate electrode G31, an active layer ACT31 including an oxide semiconductor material, a first source-drain electrode SD311, and a second source-drain electrode SD312. The channel region CL and CW31 of the switching transistor T31 can be defined by a channel length CL and a channel width CW31.

The oxide semiconductor material forming the active layer ACT31 of the switching transistor T31 can include at least one of, for example, an IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, or FIZO (FeInZnO)-based oxide semiconductor material, but the embodiments of the present disclosure are not limited thereto.

The active layer ACT31 of the switching transistor T31 includes a conducting region HH, a normal region N, and a high-mobility region H having higher mobility than the mobility of the normal region N. In the present disclosure, low mobility and high mobility are relative concepts, and by comparing the magnitudes of mobilities, relatively low mobility can be referred to as low mobility or normal mobility, and relatively high mobility can be referred to as high mobility.

The conductive region HH of the active layer ACT31 is a crystalline region that does not overlap with the gate electrode G31 and is connected to or in contact with the source-drain electrodes SD311 and SD312.

The normal region N of the active layer ACT31 overlaps with the gate electrode G31, generally forms a channel, and has lower mobility than the mobility of the conductive region HH.

The high-mobility region H of the active layer ACT31 has higher mobility than the mobility of the normal region N and lower mobility than the mobility of the conductive region HH. The high-mobility region H of the active layer ACT31 can be disposed on both sides of the normal region N.

The high-mobility region H of the active layer ACT31 of the switching transistor T31 overlaps with the edge of the gate electrode G31 and can be disposed between the normal region N and the conductive region HH.

The third driving transistor T32 of the third subpixel SP3 includes a gate electrode G32, a channel region CL and CW32 overlapping with the gate electrode G32, a third active layer ACT32 including an oxide semiconductor material, a first source-drain electrode SD321, and a second source-drain electrode SD322. The channel region CL and CW32 of the third driving transistor 312 can be defined by a channel length CL, a first channel width CW321, a second channel width CW322, and a third channel width CW323.

The oxide semiconductor material forming the third active layer ACT32 of the third driving transistor T32 can be the same as the oxide semiconductor material forming the active layer ACT31 of the switching transistor T31.

The third active layer ACT32 of the third driving transistor T32 of the third subpixel SP3 has an active spacer ASP which is a space where the third active layer ACT32 is separated in a region overlapping the gate electrode G32 of the third driving transistor T32.

The active spacer ASP does not overlap with the first source-drain electrode SD321 and the second source-drain electrode SD322 of the third driving transistor T32 and is disposed parallel to the direction of the channel length CL of the third active layer ACT32.

The active spacer ASP extends in both directions from the region overlapping with the gate electrode G32 of the third driving transistor T32 toward the first source-drain electrodes SD321 and the second source-drain electrodes SD322, and protrudes from the edge of the gate electrode G32 to have a region that does not overlap with the gate electrode G32.

The active spacer ASP extends parallel to the channel length CL of the third active layer ACT32, and the region of the active spacer ASP of the third active layer ACT32 that overlaps with the gate electrode G32 and the region of the active spacer ASP that does not overlap with the gate electrode G32 are formed as one body. When a plurality of active spacers ASP is provided, one active spacer ASP is formed as one body from the region of the active spacer ASP of the third active layer ACT32 overlapping with the gate electrode G32 to the region of the active spacer ASP that does not overlap with the gate electrode G32.

The size of the region of the active spacer ASP overlapping the gate electrode G32 of the third driving transistor T32 can be greater than the size of the region of the active spacer ASP that does not overlap the gate electrode G32 of the third driving transistor T32.

When the direction parallel to an imaginary line crossing the first source-drain electrode SD321 and the second source-drain electrode SD322 of the third driving transistor T32 is referred to as the first direction, and the direction perpendicular to the first direction is referred to as the second direction, the length of the active spacer ASP in the first direction is greater than the length of the active spacer ASP in the second direction.

Here, the first direction can be a direction parallel to the channel length CL, and the second direction can be a direction parallel to the channel widths CW31 and CW32.

The third active layer ACT32 includes a plurality of active spacers ASP.

The active spacers ASP can be disposed in the third active layer ACT32 with the same shape. Since each active spacer ASP has the same characteristics as those of one active spacer ASP described above, descriptions thereof are omitted.

The third active layer ACT32 includes a first region ACT321, a second region ACT322, and a third region ACT323 spaced apart in the second direction with the plurality of active spacers ASP interposed therebetween, and an active connection portion ACT32C connecting the first region ACT321, the second region ACT322, and the third region ACT323.

The first region ACT321 of the third active layer ACT32 has a first channel width CW321 in a region overlapping with the gate electrode G13, the second region ACT322 has a second channel width CW322 in a region overlapping with the gate electrode G32, and the third region ACT323 has a third channel width CW323 in a region overlapping with the gate electrode G32. The first region ACT321, the second region ACT322, and the third region ACT323 of the third active layer ACT32 can have a channel length CL in the regions overlapping with the gate electrode G32.

The third driving transistor T32 has the first channel width CW321, the second channel width CW322, and the third channel width CW323 according to the active spacers ASP, and can have the channel length CL for the first channel width CW121, the channel length CL for the second channel width CW321, and the channel length CL for the third channel width CW323. The third driving transistor T32 can have at least three channels separated by the active spacers ASP.

The active connection portion ACT32C may not overlap with the gate electrode G32, and can include a region where the third active layer ACT32, the first source-drain electrode SD321, and the second source-drain electrode SD322 are connected over the active spacers ASP.

The third active layer ACT32 of the third driving transistor T32 includes a conductive region HH, a normal region N, and a high-mobility region H having higher mobility than the mobility of the normal region N. The concepts of high mobility and low mobility in the present disclosure should be understood as relative concepts.

The conductive region HH of the third driving transistor T32 is a conductive region of the third active layer ACT 32 that does not overlap with the gate electrode G32 and is connected to or in contact with the source and drain electrodes SD321 and SD322. The conductive region HH of the third active layer ACT32 is located in a region that does not overlap with the gate electrode G32.

The normal region N of the third driving transistor T32 is a region that overlaps with the gate electrode G32 and into which ions for crystallization of the conductive region HH are not injected. The normal region N of the third driving transistor T32 overlaps with the gate electrode G32, generally forms a channel, and has lower mobility than the mobility of the conductive region HH.

According to an embodiment of the present disclosure, the normal region N of the third driving transistor T32 of the third subpixel SP3 is separated by the active spacers ASP.

The third active layer ACT32 of the third driving transistor T32 includes the high-mobility region H. The high-mobility region H can have higher mobility than the mobility of the normal region N and lower mobility than the mobility of the conductive region HH.

The high-mobility region H can be formed by ions of the conductive region HH diffusing toward the normal region N, ions of an etchant used in a patterning process performed during a process being injected into the exposed active layer, or by doping with ions during an annealing process.

The high-mobility region H of the third active layer ACT32 can be disposed on both sides of the normal region N between the normal region N and the conductive region HH. In addition, the high-mobility region H of the third active layer ACT32 can be further disposed at the edge of the third active layer ACT32 exposed through the active spacers ASP.

Therefore, the high-mobility region H of the third active layer ACT32 overlaps with the edge of the gate electrode G32, is in contact with the normal region N, and can be disposed between the normal region N and the conductive region HH. In addition, the high-mobility region H of the third active layer ACT32 can be disposed at the edge of the normal region N separated by the active spacers ASP. The high-mobility region H of the third active layer ACT32 overlaps with the central portion of the gate electrode G32 of the third driving transistor T32 and can be disposed at the edges of the first region ACT121, the second region ACT322, and the third region ACT323 of the third active layer ACT32 that are in contact with the active spacers ASP.

The connection portion ACT32C of the third active layer ACT32 can be disposed on both sides (based on the first direction) of the active spacer ASP to include the conductive region HH and the high-mobility region H.

The active connection portion ACT32C of the third active layer ACT32 is disposed in a region that does not overlap with the gate electrode G32 of the third driving transistor T32 and includes the conductive region H and the high-mobility region H, and thus the mobility of the active connection portion ACT32C of the third active layer ACT32 can be greater than the mobility of the first region ACT321, the second region ACT322, and the third region ACT323. In addition, the conductivity of the active connection portion ACT32C of the third active layer ACT32 can be greater than the conductivity of the first region ACT321, the second region ACT322, and the third region ACT323.

In the region where the gate electrode G32 of the third driving transistor T32 and the third active layer ACT32 overlap, the edge of the first region ACT321 of the third active layer ACT32 can become a high-mobility region H, and the center of the first region ACT321 can become a normal region N. Accordingly, in the region where the gate electrode G32 of the third driving transistor T32 and the third active layer ACT32 overlap, the mobility of the edge of the first region ACT321 of the third active layer ACT32 can be greater than the mobility of the center of the first region ACT321. In addition, the conductivity of the edge of the first region ACT321 of the third active layer ACT32 can be greater than the conductivity of the center of the first region ACT321.

In the region where the gate electrode G32 of the third driving transistor T32 and the third active layer ACT32 overlap, the edge of the second region ACT322 of the third active layer ACT32 can become a high-mobility region H, and the center of the second region ACT322 can become a normal region N. Therefore, in the region where the gate electrode G32 of the third driving transistor T32 and the third active layer ACT32 overlap, the mobility of the edge of the second region ACT322 of the third active layer ACT32 can be greater than the mobility of the center of the second region ACT322. In addition, the conductivity of the edge of the second region ACT322 of the third active layer ACT32 can be greater than the conductivity of the center of the second region ACT322.

In the region where the gate electrode G32 of the third driving transistor T32 and the third active layer ACT32 overlap, the edge of the third region ACT323 of the third active layer ACT32 can become a high-mobility region H, and the center of the third region ACT323 can become a normal region N. Accordingly, in the region where the gate electrode G32 of the third driving transistor T32 and the third active layer ACT32 overlap, the mobility of the edge of the third region ACT323 of the third active layer ACT32 can be greater than the mobility of the center of the third region ACT323. In addition, the conductivity of the edge of the third region ACT323 of the third active layer ACT32 can be greater than the conductivity of the center of the third region ACT323.

A part of the first region ACT321 in contact with the edge of the active spacer ASP of the third active layer ACT32 can be exposed during a process, and thus can become a high-mobility region H. Therefore, the mobility of the first region ACT321 in contact with the edge of the active spacer ASP of the third active layer ACT32 can be greater than the mobility of the first region ACT321 away from the edge of the active spacer ASP. In addition, the conductivity of the first region ACT321 in contact with the edge of the active spacer ASP can be greater than the conductivity of the first region ACT321 away from the edge of the active spacer ASP.

A part of the second region ACT322 in contact with the edge of the active spacer ASP of the third active layer ACT32 can be exposed during a process and thus can become a high-mobility region H. Therefore, the mobility of the second region ACT322 in contact with the edge of the active spacer ASP of the third active layer ACT32 can be greater than the mobility of the second region ACT322 away from the edge of the active spacer ASP. In addition, the conductivity of the second region ACT322 in contact with the edge of the active spacer ASP can be greater than the conductivity of the second region ACT322 away from the edge of the active spacer ASP.

A part of the third region ACT322 in contact with the edge of the active spacer ASP of the third active layer ACT32 can be exposed during a process and thus can become a high-mobility region H. Therefore, the mobility of the third region ACT323 in contact with the edge of the active spacer ASP of the third active layer ACT32 can be greater than the mobility of the third region ACT323 away from the edge of the active spacer ASP. Further, the conductivity of the third region ACT323 in contact with the edge of the active spacer ASP can be greater than the conductivity of the third region ACT323 away from the edge of the active spacer ASP.

The mobility regions of the third active layer ACT32 can be disposed in the order of the conductive region HH, the high-mobility region H, the normal region N, the high-mobility region H, and the conductive region HH in the first direction in the first region ACT321. The mobility regions of the third active layer ACT32 can be disposed in the order of the conductive region HH, the high-mobility region H, the normal region N, the high-mobility region H, and the conductive region HH in the first direction in the second region ACT322. The mobility regions of the third active layer ACT12 can be disposed in the order of the conductive region HH, the high-mobility region H, the normal region N, the high-mobility region H, and the conductive region HH in the first direction in the third region ACT323.

In the region overlapping the gate electrode G32 in the second direction, the mobility regions of the third active layer ACT32 can be disposed in the order of the high-mobility region H, the normal region N, the high-mobility region H, the active spacer ASP, the high-mobility region H, the normal region N, the high-mobility region H, the active spacer ASP, the high-mobility region H, the normal area N, and the high-mobility region H.

As described above, the third active layer ACT32 of the third driving transistor T32 of the third subpixel SP3 according to an embodiment of the present disclosure has a plurality of active spacers ASP. The number of active spacers ASP of the third active layer ACT32 of the third driving transistor T32 is greater than the number of active spacers ASP of the first active layer ACT12 of the first driving transistor T12 of the first subpixel SP1.

The third active layer ACT32 can have a plurality of high-mobility regions H in the direction of the channel length CL in the channel region through active spacers ASP. Compared to the first subpixel SP1 and the second subpixel SP2, the third active layer ACT32 can have a plurality of active spacers ASP or have more active spacers ASP to include a larger number of high-mobility regions H than in the first subpixel SP1 and the second subpixel SP2.

According to an embodiment of the present disclosure, the third driving transistor T32 of the third subpixel SP3 can lower the resistance value through the plurality of high-mobility regions H disposed in the third active layer ACT32, and thus increase the current. When the third subpixel SP13 has lower luminous efficacy than the first subpixel SP1 or the second subpixel SP2, a greater amount of current is required for the third subpixel SP3. However, the amount of current can be increased in the third driving transistor T32 through the plurality of active spacers ASP in the third subpixel SP3, and thus the luminance can be improved and the characteristics required for the third subpixel SP3 can be achieved.

In addition, the third driving transistor T32 of the third subpixel SP3 according to an embodiment of the present disclosure can increase the ON current, and thus the threshold voltage of the third driving transistor T32 can be lowered, stress of the third driving transistor T32 can be reduced, deterioration of the third driving transistor T32 can be prevented, and power consumption can be reduced.

In the case of a transistor having an active layer including an oxide semiconductor material, the transistor can be subjected to PBTS when the active layer deteriorates during long-term operation or in a high-temperature environment, and the threshold voltage Vth can shift in the (+) direction due to the PBTS.

However, in the case of the third driving transistor T32 of the third subpixel SP3 according to the present disclosure, a plurality of high-mobility regions H is disposed at the edges of the third active layer ACT32 exposed through a plurality of active spacers ASP in the region where the third active layer ACT32 and the gate electrode G32 overlap, and thus even if the third driving transistor T32 is driven for a long time or in a high-temperature environment, the degree of deterioration can be reduced.

Therefore, the display device 100 according to the present disclosure can stabilize the PBTS characteristic of the third driving transistor T32 of the third subpixel SP3, thereby providing a driving transistor with a small variation in the threshold voltage, and can improve reliability.

In addition, according to an embodiment of the present disclosure, the third driving transistor T32 of the third subpixel SP3 has one third active layer ACT32 having different mobilities by including active spacers ASP instead of having active layers having different mobilities through a separate process.

Since the active spacers ASP of the third subpixel SP3 can be formed without performing a separate additional process, the display device 100 according to an embodiment of the present disclosure can reduce production energy and reduce greenhouse gas emissions that can occur due to the manufacturing process through process optimization, thereby implementing ESG (Environmental/Social/Governance).

With references to FIGS. 11 and 12, in view of FIG. 5, each of the conductive region HH, the normal region N, the high-mobility region H, and the active spacer ASP can have lengths in the second direction in FIG. 11. Accordingly, FIGS. 11 and 12 show that the arrangement of the active layer ACT31 of the switching transistor T31, which shows a sequence of the conductive region HH, the high-mobility region H, the normal region N, the high-mobility region H and the conductive region HH from the first source-drain electrode SD311 to the second source-drain electrode SD312. Meanwhile, the arrangement of the third active layer ACT32 of the third driving transistor T32 shows a sequence of the conductive region HH, the high-mobility region H, the normal region N, the high-mobility region H, the active spacer ASP, the high-mobility region H, the normal region N, the high-mobility region H, the active spacer ASP, the high-mobility region and the conductive region HH from the first source-drain electrode SD321 to the second source-drain electrode SD322. Thus, the conductive region HH, the high-mobility region H, the normal region N and/or the active spacer ASP in the switching transistor T31 and the third driving transistor T32 generally extend in the second direction, which is the same direction as a longitudinal direction of the gate electrodes G31 and G32.

It is also noted that the cross-sectional view of the third active layer ACT32 of the third driving transistor T32 in FIG. 12 is provided by a square wave portion of the line III-III’ in FIG. 11. In this regard, referring to the vertical section of the line III-III’ in FIG. 11 for third driving transistor T32, which is depicted in cross-sectional view in FIG. 12, the pair of high-mobility regions H on opposite sides of each active spacer ASP can be portions of the high-mobility region H that extend in the first direction that is intersecting the second direction. Thus, the portion (i.e., a first portion) of the high-mobility region H that is immediately adjacent to the active spacer ASP extends in a direction different from the portion (i.e., a second portion) of the high-mobility region H that is immediately adjacent the conductive region HH in the first driving transistor T12. In this regard, the first portion of the high-mobility region H extends in the first direction and the second portion of the high-mobility region H extends in the second direction. Also, the first and second portions of the high-mobility region H can be in contact or be connected, but such is not required, so that the first and second portions of the high-mobility region H can be disconnected or not in contact. In embodiments of the present disclosure, widths of the first and second portions of the high-mobility region H can be the same or different. For example, the width of the first portion of the high-mobility region H can be smaller or greater than the width of the second portion of the high-mobility region H. In FIG. 12, the normal region N between the two active spacers ASP in a middle portion of the third active layer ACT32 can be encircled by the high-mobility region H, whereby two first portions parallel to each other and two second portions that are parallel to each other can encircle the normal region N in the middle portion of the third active layer ACT32, for example, but such is not required.

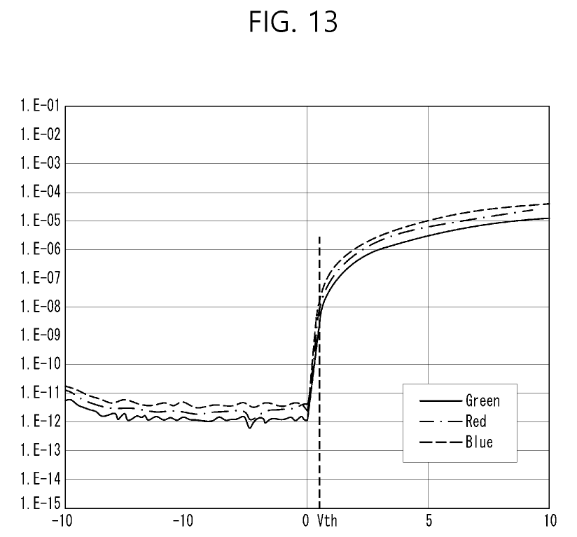

Referring to FIG. 13, when the first to third subpixels SP1, SP2, and SP3 according to the embodiments of the present disclosure are applied, the threshold voltage values become similar and stabilized although the first to third subpixels SP1, SP2, and SP3 have different luminous efficacies. Here, when the first subpixel SP1 is set to emit red light, the first driving transistor T12 of the first subpixel SP1 has at least one active spacer ASP. When the second subpixel SP2 is set to emit green light, the second driving transistor T22 of the second subpixel SP2 does not have the active spacer ASP. When the third subpixel SP3 is set to emit blue light, the third driving transistor T32 of the third subpixel SP3 has a larger number of active spacers ASP than the first driving transistor T12 of the first subpixel SP1 and the second driving transistor T22 of the second subpixel SP2.

For example, the second driving transistor T22 of the second subpixel SP2 (e.g., green subpixel) having the highest luminance efficiency does not have an active spacer ASP, and the first driving transistor T12 of the first subpixel SP1 (e.g., red subpixel) has an active spacer ASP. In addition, the third driving transistor T32 of the third subpixel SP3 (e.g., blue subpixel) having the lowest luminous efficacy has a larger number of active spacers ASP than the first driving transistor T12 of the first subpixel SP1. As shown in FIG. 13, the threshold voltages of the first driving transistor T12 of the first sub-pixel SP1 and the third driving transistor T32 of the third sub-pixel SP3 can be reduced. Therefore, the display device 100 according to the present disclosure can reduce power consumption.

The display device 100 according to the present disclosure can match the required current characteristics and set values through the active spacer ASP even if multiple subpixels SP1, SP2, and SP3 display different colors. In addition, the display device 100 according to the present disclosure can stabilize the PBTS characteristic of the driving transistor of each subpixel, thereby improving reliability.

The embodiments of the present disclosure can dispose the active spacers ASP of the display device without a separate additional process, thereby reducing production energy and thus can achieve ESG (Environments/Social/Governance).

The display device according to the present disclosure can include a driving transistor having a small variation in the threshold voltage by stabilizing the PBTS characteristic of the driving transistor of each subpixel.

The embodiments of the present disclosure can lower the threshold voltage of the driving transistors of the subpixels, thereby reducing stress, preventing deterioration of the driving transistors, and reducing power consumption.

The embodiments of the present disclosure can match the current characteristics and set values required for subpixels displaying different colors.

The embodiments of the present disclosure can improve the reliability of transistors including an oxide semiconductor layer.

In addition, the embodiments of the present disclosure can achieve ESG (Environments/Social/Governance) by improving the reliability of the display device and reducing production energy and power consumption.

It will be apparent to those skilled in the art that various modifications and variations can be made in the present disclosure without departing from the spirit or scope of the present disclosure. Thus, it is intended that the present disclosure covers the modifications and variations of the present disclosure provided they come within the scope of the appended claims and their equivalents.

What is claimed is:

1. A display device comprising:
a substrate;
a first subpixel, a second subpixel, and a third subpixel disposed on the substrate, the first subpixel emitting light of a first wavelength, the second subpixel emitting light of a second wavelength shorter than the light of the first wavelength, and the third subpixel emitting light of a third wavelength shorter than the light of the second wavelength;
a first driving transistor at the first subpixel, a second driving transistor at the second subpixel, and a third driving transistor at the third subpixel, and the first, second and third transistors being on the substrate; and
a plurality of switching transistors at the first, second and third subpixels, respectively,
wherein a first active layer of the first driving transistor has an active spacer where the first active layer overlaps a first gate electrode of the first driving transistor, and a third active layer of the third driving transistor has an active spacer where the third active layer overlaps a third gate electrode of the third driving transistor, the active spacers being spaces that separate the first active layer and the third active layer, respectively.

2. The display device of claim 1, wherein:
each of the plurality of switching transistors includes a first source-drain electrode, a second source-drain electrode, a gate electrode, and an active layer overlapping the gate electrode,
the active layers of the plurality of switching transistors do not include active spacers, and
wherein the active layer, the first driving active layer and the third driving active layer include an oxide semiconductor material.

3. The display device of claim 1, wherein the active spacers do not overlap first source-drain electrodes and second source-drain electrodes of the first driving transistor and the third driving transistor, respectively, and the active spacers are disposed parallel to a direction of channel lengths of the first active layer and the third active layer.

4. The display device of claim 1, further comprising:
a gate insulating layer disposed on the first active layer and the third active layer on the substrate, wherein the first gate electrode of the first driving transistor, a second gate electrode of the second driving transistor, and the third gate electrode of the third driving transistor are disposed on the gate insulating layer; and
an insulating layer disposed between the substrate and both of the first active layer and the third active layer,
wherein the gate insulating layer is disposed in the active spacers, and the gate insulating layer is in contact with the insulating layer disposed under the first and third active layers at the active spacers.

5. The display device of claim 1, wherein:
the active spacer of the first active layer extends in opposite directions from where the first active layer overlaps the first gate electrode of the first driving transistor towards a first source-drain electrode and a second source-drain electrode of the first driving transistor, and the active spacer protrudes from edges of the first gate electrode to have portions not overlapping the first gate electrode,
the active spacer of the third active layer extends in opposite directions from where the third active layer overlaps the third gate electrode of the third driving transistor towards a first source-drain electrode and a second source-drain electrode of the third driving transistor, and the active spacer protrudes from edges of the third gate electrode to have portions not overlapping the third gate electrode, and
the active spacers are disposed to extend parallel to channel lengths of the first and third active layers, respectively.

6. The display device of 5, wherein:
a portion of the active spacer overlapping the first gate electrode of the first driving transistor is integral with the portion of the active spacer extending in the opposite directions toward the first source-drain electrode and the second source-drain electrode of the first driving transistor and not overlapping the first gate electrode, and
a portion of the active spacer overlapping the third gate electrode of the third driving transistor is integral with the portion of the active spacer extending in the opposite directions toward the first source-drain electrode and the second source-drain electrode of the third driving transistor and not overlapping the third gate electrode.

7. The display device of claim 1, wherein:
a size of a portion of the active spacer overlapping the first gate electrode of the first driving transistor is greater than a size of a portion of the active spacer not overlapping the first gate electrode of the first driving transistor, and
a size of the portion of the active spacer overlapping the third gate electrode of the third driving transistor is greater than a size of a portion of the active spacer not overlapping the third gate electrode of the third driving transistor.

8. The display device of claim 5, wherein:
based on a direction parallel to an imaginary line crossing the first source-drain electrode and the second source-drain electrode of each of the first driving transistor and third driving transistor being defined as a first direction, and a direction perpendicular to the first direction being defined as a second direction,
lengths of the active spacers in the first direction are greater than lengths of the active spacers in the second direction.

9. The display device of claim 5, wherein:
based on a direction parallel to an imaginary line crossing the first source-drain electrode and the second source-drain electrode of each of the first driving transistors being defined a first direction, and a direction perpendicular to the first direction being defined as a second direction,
the first active layer includes a first region and a second region spaced apart in the second direction with the active spacer interposed between the first region and the second region, and an active connection portion connecting the first region and the second region in the first direction and not overlapping the first gate electrode of the first driving transistor, and
a mobility of the active connection portion is greater than a mobility of the first region and the second region.

10. The display device of claim 9, wherein:
a mobility of an edge of the first region in the portion overlapping the first gate electrode of the first driving transistor is greater than a mobility of a center of the first region, and
a mobility of an edge of the second region in the portion overlapping the first gate electrode of the first driving transistor is greater than mobility of a center of the second region.

11. The display device of claim 9, wherein:
a mobility of the first region in contact with the edge of the active spacer is greater than mobility of the first region away from the edge of the active spacer, and
a mobility of the second region in contact with the edge of the active spacer is greater than mobility of the second region away from the edge of the active spacer.

12. The display device of claim 1, wherein the first subpixel displays red, the second subpixel displays green, and the third subpixel displays blue.

13. The display device of claim 12, wherein a second active layer of the second driving transistor of the second subpixel does not have an active spacer in a region overlapping a second gate electrode of the second driving transistor of the second subpixel.

14. The display device of claim 13, wherein:
the first wavelength is in a red wavelength range, the second wavelength is in a green wavelength range, the third wavelength is in a blue wavelength range, and
a number of active spacers of the first active layer of the first driving transistor at the first subpixel is greater than the number of active spacers of the second active layer of the second driving transistor at the second subpixel.

15. The display device of claim 12, wherein:
the first subpixel emits red light, the second subpixel emits green light, the third subpixel emits blue light, and
a number of the active spacer of the third active layer of the third driving transistor at the third subpixel is greater than each of a number of the active spacer of the first active layer at the first subpixel and a number of the active spacer of the second active layer at the second subpixel.

16. The display device of claim 1, wherein an oxide semiconductor material included in the first and third active layers comprises at least one of an IZO (InZnO)-based, IGO (InGaO)-based, ITO (InSnO)-based, IGZO (InGaZnO)-based, IGZTO (InGaZnSnO)-based, GZTO (GaZnSnO)-based, GZO (GaZnO)-based, ITZO (InSnZnO)-based, and FIZO (FeInZnO)-based oxide semiconductor material.

17. A display device comprising:
a substrate;
a plurality of subpixels on the substrate and including a first subpixel and a second subpixel,
a first driving transistor at the first subpixel and a second driving transistor at the second subpixel;
at least one switching transistor on the substrate; and
a first gate electrode overlapping the first driving transistor and a second gate electrode overlapping the second driving transistor,
wherein the first driving transistor includes a first active layer including an active spacer and the second driving transistor includes a second active layer not including the active spacer,
wherein the active spacer includes a hole that penetrates the first active layer, and
wherein the first gate electrode overlaps the active spacer.

18. The display device of claim 17, wherein the first gate electrode and the second gate electrode extend in a second direction, and
wherein the active spacer extends in a first direction that intersects the second direction.

19. The display device of claim 18, wherein the first active layers further includes a high-mobility region, a normal region and a conductive region in sequential order on each of opposite sides of the active spacer in an outward direction away from the active spacer along the first direction.

20. The display device of claim 18, wherein the second active layer includes a normal region, and
wherein the second active layer further includes a high-mobility region and a conductive region in sequential order on each of opposite sides of the normal region in an outward direction away from normal region along the first direction.
